(19) United States
(12) Patent Application Publication
(10) Pub. No.: US 2010/0103634 A1
(43) Pub. Date: Apr. 29, 2010

(54) FUNCTIONAL-DEVICE-EMBEDDED CIRCUIT BOARD, METHOD FOR MANUFACTURING THE SAME, AND ELECTRONIC EQUIPMENT

(76) Inventors: Takuo Funaya, Tokyo (JP); Shintaro Yamamichi, Tokyo (JP); Hideya Murai, Tokyo (JP); Kentaro Mori, Tokyo (JP); Katsumi Kikuchi, Tokyo (JP)

Correspondence Address: Mr. Jackson Chen, 6535 N. STATE HWY 161, IRVING, TX, 75039, US

(21) Appl. No.: 12/593,489

(22) PCT Filed: Mar. 28, 2008
(86) PCT No.: PCT/JP2008/056199

§ 371 Date: Sep. 28, 2009

(30) Foreign Application Priority Data
Mar. 30, 2007 (JP) 2007-093083
Jan. 9, 2008 (JP) 2008-002159

(51) Int. Cl. H05K 1/11; H05K 1/09; H05K 1/16; H05K 1/14; H05K 3/02

(52) U.S. Cl. 361/761; 174/262; 174/257; 174/260; 361/803; 29/846

(57) ABSTRACT

A circuit board includes a functional device, a circuit board embedding therein the functional device, and first and second conductive-wiring layers formed on the front and rear surfaces of the circuit board to sandwich therebetween the functional device and each include at least one conductor layer. The surface of each of the outermost patterned interconnections of the first conductive-wiring layer is exposed, and the surface of a first dielectric layer isolating the outermost patterned interconnections from one another protrudes from the surface of the each of the patterned interconnections. The patterned interconnections of the second conductive-wiring layer are connected to respective electrode terminals of the functional device, and the surface of a second dielectric layer isolating the electrode terminals from one another is substrate within the same plane as the surface of the electrode terminals disposed adjacent to the second dielectric layer.

### TECHNICAL FIELD

The present invention relates to a functional-device-embedded circuit board, a method for manufacturing the same and an electronic equipment and, more particularly, to a functional-device-embedded circuit board that embeds therein one or a plurality of functional devices, a method for manufacturing the same, and an electronic equipment that includes the functional-device-embedded board.

### BACKGROUND ART

A functional-device-embedded circuit board (hereinafter, may be simply referred to as circuit board) is a circuit board that embeds therein a functional device, such as an LSI. Since the circuit board can avoid more likely application of a mechanical stress onto the electrode portion of the functional device, as compared to other mounting techniques, such as a wire bonding and a flip-chip bonding, that directly connect the functional device to the printed-circuit board, damage to the electrode portion can be suppressed to thereby improve the reliability. In addition, since the electrode portion of the functional device is not exposed on the surface, corrosion of the electrode portion can be suppressed.

The circuit board described in JP-1999-233678A is used as an IC package, wherein a dielectric film having a cavity therein is formed on a metal plate, a semiconductor device is mounted within the cavity on the metal plate, with the active surface thereof on which the electrode terminals are provided being upward, i.e., in a so-called face-up, and a plurality of build-up wiring layers are formed thereon using a photosensitive resin. In the case of using the photosensitive resin, inclusion of silica fillers or glass cloth causes a loss of resolution whereby a sufficient amount of resin for maintaining the strength reliability cannot be used, to thereby incur a problem in that reliability as the package is lost. In addition, since the build-up wiring is formed only on the surface of the semiconductor device including the electrode terminals, the conductive-wiring layers are only formed on the one side to cause an inconvenience that it cannot be used as the circuit board other than the package. Furthermore, the package attached with the metal plate has a heavy weight and a larger external thickness if it is the semiconductor package that does not need heat radiation.

The circuit board described in JP-2002-359324A is formed as a semiconductor package, wherein a semiconductor device including protruding electrodes and a mold substrate having a protrusion at the portion corresponding to the protruding electrodes of the semiconductor device are opposed to each other and bonded together, the gap between the semiconductor device and the mold substrate is filled with fluid resin, and solder balls are formed in the recess formed on the resin overlying the protruding electrodes obtained by removing the mold substrate after curing the resin. The semiconductor package, if it must be formed to have the same size as the semiconductor device and the wiring rule of the semiconductor device is of a narrow pitch, inhibits the wiring rule from being increased and thus causes a problem in that it cannot be used for surface mounting etc. Furthermore, there occurs a deviation upon bonding together the mold substrate and the protruding electrodes, to thereby cause a risk that an opening area above the protruding electrodes is narrower, and incur a problem in that the wettability of the solder balls is degraded. The protruding electrodes, which are formed only on the side of electrode terminals of the semiconductor device, do not have a function of interconnections, thereby causing an inconvenience that it cannot be used as the circuit board.

In the circuit board described in JP-2003-229512A, BGA electrode pads are formed in advance on a metal mold plate, a semiconductor device is connected onto the build-up conductive wiring by flip-chip bonding, flow of under-fill resin is supplied, a board to which the semiconductor device is connected is encapsulated with mold resin, and thereafter the metal mold plate is removed to expose the BGA electrode pads on the surface to obtain the semiconductor package. In this case, since the interconnections are formed only on one side of the semiconductor device near the electrode terminals, i.e., the conductive-wiring layer is formed only on a single surface of the package, it cannot be used as the circuit board other than time package. Moreover, a metal heat sink cannot be attached onto the rear surface of the semiconductor chip, a heat radiation effect cannot be expected. Furthermore, since the semiconductor device is connected by an ordinary flip-chip bonding after forming the conductive-wiring layer of the circuit board, manufacture of the circuit board as well as mounting of the semiconductor device is costly similarly to an ordinary case, whereby a cost reduction cannot be expected.

In the circuit board described in JP-2002-064178A, a semiconductor device is connected to the circuit board by a flip-chip bonding etc., and a plurality of this type of boards are stacked alternately with circuit boards including therein via-plugs obtained by filling a cavity with conductive paste, and solder balls are attached onto the bottom substrate, to obtain a semiconductor-stacked package. In this case, the configuration wherein the boards including the cavity and semiconductors are alternately stacked one on another causes a problem in that an organic resin layer having little rigidity is formed on both the top and bottom of the semiconductor device, whereby fragile semiconductor silicon or GaAs is split at once by application of a pressure thereto. The resin layer on which the chip is mounted is subjected to formation of interconnections while using a copper sheet affixed onto one side thereof, whereby the interconnections are formed by an etching to cause a problem in that narrow-pitch wiring cannot be provided within the package, unlike the case of a semi-additive technique. Due to the configuration wherein the semiconductor device is connected by a flip-chip bonding, manufacture of the circuit board and mounting the semiconductor is costly as in an ordinary case, whereby a problem occurs that cost reduction cannot be expected.

In the circuit board described in JP-2005-217205A, semiconductor devices are stacked one on another using semiconductor chips and spacer chips including therein via-holes. In this case, since the interconnections cannot be spread to excess the size of the semiconductor, and the structure is such that the conductive-wiring layer is exposed only on one side of the package board, there is a defect that it is only used as a package, and cannot be used as a circuit board. In addition, the interconnection distance with respect to the other electronic parts is extremely long due to the connection via a mother board in a surface mounting, thereby incurring a problem in that a high-speed electric performance cannot be obtained as a product, although the high-speed electric performance is excellent only within the package.

In the circuit boards described in JP-2001-332863A, JP-2001-339165A, JP-2001-352174A, JP-2002-084074A, JP-2002-170840A and JP-2002-246504A, through-holes are formed in the core board, a semiconductor chip is mounted therein by using adhesive with the active surface being upward in a face-up, and conductive-wiring layers are stacked on the electrode terminals. Via-holes are formed in the core board, and wiring layers are stacked on both the surfaces of the core board by using a semi-additive technique. In addition, the semiconductor device is mounted on a metal or ceramic heat sink in a face-up, and conductive-wiring layers are stacked onto the electrode terminals. Since a portion of organic resin is only the element located right under the location of through-holes of the core board on which the semiconductor chip is to be mounted, there is a problem in that the semiconductor chip may be split due to a pressure applied during mounting the semiconductor chip because of the bending moment being applied onto the soft resin if a thin chip that is thinner than around 100 μm is used. In addition, if the via-holes am formed in the resin core board embedding therein a semiconductor chip by using a drill etc., there occurs a problem in that a muss is applied onto the semiconductor chip embedded in the vicinity of the via-holes to split the chip due to an insufficient rigidity of the resin during the drilling process. Thus, the via-holes must be significantly apart from the embedded semiconductor chip, thereby increasing the outer size of the board. The product wherein the semiconductor chip is mounted on a metal or ceramic heat sink in a face-up structure and conductive-wiring layers are stacked on the electrode terminals has a drawback that the conductive-wiring layers are formed only on one side thereof, conductive-wiring layers are not provided on the side near the heat sink, and thus cannot be used as the circuit board.

The circuit board described in JP-2006-339421A is such that the semiconductor chip, which is obtained by forming Au stud bumps or solder bumps etc. after forming a dielectric film and a conductor layer on a supporting substrate in a build-up technique, is subjected to a so-called flip-chip process in a face-down structure by coupling the bumps to the conductive wiring on the supporting substrate, thereafter subjected to reinforcement using under-filling, the circumference of the connected semiconductor chip is covered by resin, and thereafter formation of vias, dielectric films and conductor layers is performed by using a build-up technique. The total cost in this process for forming the semiconductor-chip-embedded board is not reduced below the total cost that includes the cost for forming the board, the cost for coupling process in a flip-chip bonding and the cost for the under-filling, as compared to the conventional case where the semiconductor chip is bonded onto the circuit board by using a flip-chip, due to the fact that the semiconductor chip embedded in the board is bonded by flip-chip bonding. Thus, there is a problem in that the process cannot reduce the cost. In addition, due to use of the flip-chip technique, it is needed to apply a heat stress onto the dielectric film at a high temperature of around 300° for about 30 seconds during bonding the bump onto the conductive wiring on the supporting substrate if the Au stud bumps are used, thereby causing degradation of resin and the problem of decrease in the reliability of products. If solder is used for the bumps, the bonding portion itself has the problem in heat resistance, thereby causing the problem of breakage of bump-bonded portion in the semiconductor-chip-embedded board, due to a reflow treatment during the surface mounting, thereby causing a lower reliability of products. On the surface of the semiconductor chip opposing the supporting substrate, the conductive wiring is not flat, thereby incurring a defect that the later mounting process using the semiconductor-chip-embedded board proves a poor workability.

In the circuit board described in JP-2005-236039A, a positioning pattern is formed on the side surface of chip by using a conductive wiring in the vicinity of a position of the transfer substrate on which the semiconductor chip is to be mounted. However, if the positioning pattern is larger than the size of the mounted chip, the chip moves after the mounting, thereby causing the problem of deviation of the chip-mounted position. If the positioning pattern is equivalent to the chip size, the chip may collide with the positioning pattern during mounting the chip by using a mounting device, to incur split of the chip and thus decrease the reliability of products. If adhesive is used on the position on which the chip contacts the transfer substrate, the positioning mark does not have a function of preventing the chip movement in the horizontal direction. Thus, there is the problem of deviation occurring in the positional relationship between the vias positioned on the side surface of chip and the electrode terminals of chip. After removing the transfer substrate, the bottom surface of chip is exposed, whereby there is a risk that the bending or collision that occurs in the later process may split the chip, thereby causing the problem in the reliability and yield of products. On the surface through which the surface of IC chip is exposed, the surface of wiring pattern is flush with the resin layer on the side surface thereof, whereby there occurs a short-circuit failure in the wiring during the solder bonding if the solder resist layer is not provided. If post electrodes are to be provided on the side surface of chip, Cu posts are formed in advance by plating, embedded within resin and then subjected to post grinding. At this stage, the shape of vias as viewed from the sectional surface of the board is a trapezoid, wherein the inner diameter thereof is smaller at one end and larger at the other end. Thus, an internal stress occurring in the thickness direction of the board, with the embedded portion of chip being the center, causes the problem of peel-off between the vias and the dielectric resin.

The circuit board described in JP-2006-19342A has the problem that a mounting process using the conductive wiring formed on both the surfaces cannot be performed because a metal shield layer and a magnetic-body shield layer are formed on one of the surfaces of the IC-chip-embedded board. In addition, since the entire surface opposing the electrode terminals of IC chip directly contacts a mound pattern layer, the chip is warped by the difference in the thermal coefficient of expansion between the Si chip and the metal configuring the ground, thereby causing split of the chip if the chip is thin.

In JP-2001-250902A and JP-2001-237632A, the chip-embedded boards in which a conductor layer is formed only on one of the front and rear surfaces thereof are connected together through both the chips by using the multilevel interconnections. However, since vias cannot be provided in the vicinity of chips, the line length is increased to thereby cause the problem in the high-speed electric performance.

In the above conventional circuit boards, there are problems as recited hereinafter. The problems are such that when a functional device is to be embedded and if the circuit board including an organic resin as a base material and having no supporting substrate is used to underlie the mounting surface of the functional device, the portion of the organic resin of the circuit board is inflected due to the mounting load, thereby generating a bending stress on the functional device itself to damage the device if the functional device itself is comprised of silicon, ceramic etc.

### SUMMARY OF THE INVENTION

The present invention is devised in view of the problems as described above, and it is an object of the present invention to realize the improvement in the reliability of products and reduction in the cost in relation to formation and mounting of the circuit board by allowing the connection of the functional device to the circuit board and formation of the circuit board to be performed simultaneously with each other.

The present invention provides, in a first aspect thereof, a circuit board including: at least one functional device; a wiring board embedding therein the functional device; and first and second wiring layers disposed on front and rear surfaces of the circuit board to sandwich therebetween the functional device and each including at least one conductor layer, wherein: each of patterned interconnections in an outermost layer of the first conductive-wiring layer is exposed, and a first dielectric layer that isolates the patterned interconnections in the outermost layer has a surface protruding from a surface of the patterned interconnections; and the patterned interconnections in the second wiring layer is connected to electrode terminals of the functional device, and at least a part of a surface of a second dielectric layer isolating the electrode terminals from one another and at least a part of a surface of the electrode terminals are substantially in a same plane.

The present invention provides, in a second aspect thereof, a circuit board wherein the circuit board and a wiring board are stacked one on another in a thickness direction, and a wiring layer of the circuit board and a wiring layer of the wiring board are connected together by a conductive paste or lead-free solder paste including at least one species of element selected from the group consisting of Sn, Ag, Cu, Bi, Zn and Pb.

The present invention provides, in a third aspect thereof, an electronic equipment including the above circuit board.

The present invention provides, in a fourth aspect thereof, a circuit-board manufacturing method including the steps of forming at least one first conductive-wiring layer on a supporting substrate; mounting a functional device on the first conductive-wiring layer, covering the functional device by a dielectric resin layer; removing an upper part of the dielectric resin layer so that the surface of the dielectric resin layer is flush with a surface of the electrode terminals of the functional device; forming a second conductive-wiring layer that is a conductive-wiring layer connected the electrode terminals, and removing the supporting substrate.

The present invention provides, in a fifth aspect thereof, a circuit-board manufacturing method including the step of opposing two of the circuit boards manufactured by the above method against each other, and connecting together both the circuit boards by using an adhesive layer obtained by embedding conductive paste or solder paste within the via-hole.

The present invention provides, in a sixth aspect thereof, a circuit-board manufacturing method including the steps of opposing the functional-device board manufactured by the above method against a wiring board, and connecting together both the circuit boards by using an adhesive layer obtained by embedding conductive paste or solder paste within the via-hole.

The above and other objects, features and advantages of the present invention will be more apparent from the following description, referring to the accompanying drawings.

### BRIEF DESCRIPTION OF THE DRAWINGS

FIG. 1 is a sectional view of a first exemplary embodiment of the circuit board of the present invention.

FIG. 2 is a sectional view showing the vicinity of electrode terminals 53 in FIG. 1 while enlarging the same.

FIG. 3 is a sectional view of a circuit board according to a modified example of the first exemplary embodiment.

FIG. 4A is sectional view of a second exemplary embodiment of the circuit board of the present invention, and FIG. 4B is a sectional view of a circuit board according to a modified example of the second exemplary embodiment.

FIG. 5 is a sectional view of a third exemplary embodiment of the circuit board of the present invention.

FIG. 6 is a sectional view of a circuit board according to a first modified example of the third exemplary embodiment.

FIG. 7 is a sectional view of a circuit board according to a second modified example of the third exemplary embodiment.

FIG. 8 is a sectional view showing the state where electronic parts and a functional device are mounted on the circuit board of FIG. 7.

FIG. 9 is a sectional view showing the state where the solder bumps are formed on the circuit board of FIG. 6.

FIG. 10 is a sectional view showing the state where electronic parts are mounted on the circuit board of FIG. 7 and solder bumps are formed.

FIG. 11 is a sectional view of a fourth exemplary embodiment of the circuit board of the present invention.

FIG. 12 is a sectional view of a fifth exemplary embodiment of the circuit board of the present invention.

FIG. 13 is a sectional view of a sixth exemplary embodiment of the circuit board of the present invention.

FIG. 14 is a sectional view of a seventh exemplary embodiment of the circuit board of the present invention.

FIG. 15 is a sectional view of a circuit board according to a modified example of the seventh exemplary embodiment.

FIG. 16 is a sectional view of an eighth exemplary embodiment of the circuit board of the present invention.

FIG. 17 is a sectional view of a circuit board according to a first modified example of the eighth exemplary embodiment.

FIG. 18 is a sectional view of a circuit board according to a second modified example of the eighth exemplary embodiment.

FIG. 19 is a top plan view of a ninth exemplary embodiment of the circuit board of the present invention.

FIGS. 20(a) to 20(h) are sectional views of respective fabrication stages in a first exemplary embodiment of the circuit-board manufacturing process of the present invention.

FIGS. 21(a) to 21(j) are sectional views of respective fabrication stages in second exemplary embodiment of the circuit-board manufacturing process of the present invention.

FIGS. 22(a) to 22(d) are sectional views of respective fabrication stages in a third exemplary embodiment of the circuit-board manufacturing process of the present invention.

FIGS. 23(a) to 23(d) are sectional views of respective fabrication stages in a fourth exemplary embodiment of the circuit-board manufacturing process of the present invention.

FIGS. 24(a) and 24(b) are sectional views of respective fabrication stages in a fourth exemplary embodiment of the circuit-board manufacturing process of the present invention.

FIGS. 25(a) and 25(b) are sectional views of respective fabrication stages in a fourth exemplary embodiment of the circuit-board manufacturing process of the present invention.

FIG. 26 is a sectional view showing a fabrication stage in a fifth exemplary embodiment of the circuit-board manufacturing process of the present invention.

FIG. 27 is sectional view of a circuit board according to a first comparative example of the first exemplary embodiment.

FIG. 28 is a sectional view of a circuit board according to a second comparative example of the first exemplary embodiment.

FIG. 29 is a sectional view of a tenth exemplary embodiment of the circuit board of the present invention.

FIG. 30 is a sectional view of a circuit board according to a first modified example of the tenth exemplary embodiment.

FIG. 31 is a sectional view of an eleventh exemplary embodiment of the circuit board of the present invention.

FIGS. 32(a) to 32(d) are sectional views of twelfth exemplary embodiments of the circuit board of the present invention.

FIGS. 33(a) to 33(i) are sectional views of respective fabrication stages in sixth exemplary embodiment of the circuit-board manufacturing process of the present invention.

FIGS. 34(a) to 34(j) are sectional views respective fabrication stages in a seventh exemplary embodiment of the circuit-board manufacturing method of the present invention.

FIGS. 35(a) to 35(h) are sectional views of respective fabrication stages in a an eighth exemplary embodiment of the circuit-board manufacturing process of the present invention.

FIGS. 36(a) to 36(f4) are sectional views of respective fabrication stages in a ninth exemplary embodiment of the circuit-board manufacturing process of the present invention.

### BEST MODE OF CARRYING OUT THE INVENTION

### Functional-Element-Embedded Circuit Board

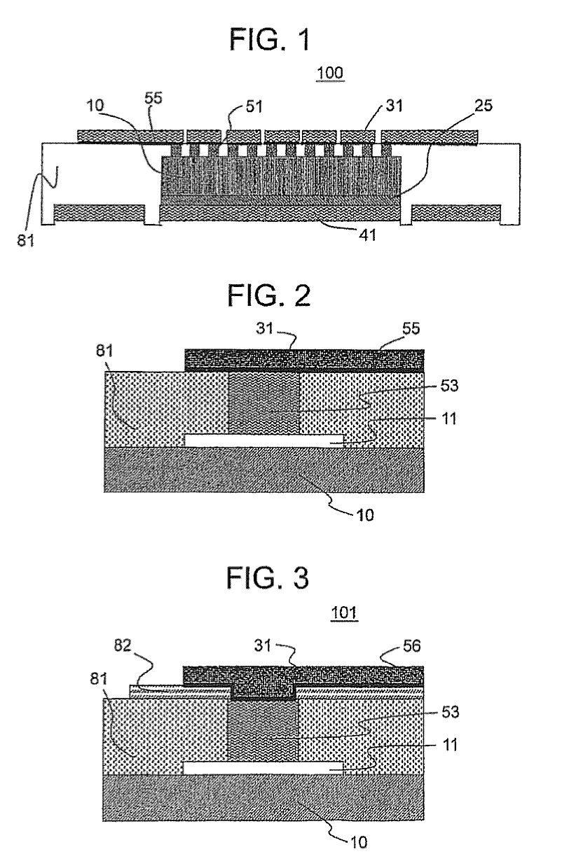

Hereinafter, exemplary embodiments of the present invention will be described in more detail with reference to the accompanying drawings. FIG. 1 is a sectional view of a first exemplary embodiment of the functional-device-embedded circuit board (hereinafter, referred to simply as circuit board) of the present invention. The circuit board 100 includes a functional device 10 including a plurality of electrode terminals 53 on the front side thereof. On the front side of the functional device 10, a conductive-wiring layer 31 is formed in connection with the electrode terminals 53. On the rear side of the functional device 10, a conductive-wiring layer 41 is formed on the rear surface of the functional device 10 with an intervention of an adhesive layer 25. The conductive-wiring layers 31 and 41 are formed in an area larger than the area of the functional device 10. A dielectric resin layer 81 is formed between the functional device 10 and the conductive-wiring layer 31 and conductive-wiring layer 41 and between the plurality of electrode terminals 53.

FIG. 2 is a sectional view showing a vicinity of the electrode terminals 53 in FIG. 1 while enlarging the same. The surface of the electrode terminals 53 is formed at the same height as the surface of dielectric resin layer 81. A plating seed layer 55 is formed between the electrode terminals 53 and dielectric resin layer 81 and the conductive-wiring layer 31.

The configuration wherein the surface of the electrode terminals 53 is formed at the same height as the surface of dielectric resin layer 81 reduces the number of points of inflection on the surface of the electrode terminals 53 and conductive-wiring layer 31, thereby improving the connection reliability between the electrode terminals 53 and the conductive-wiring layer 31. In the process for forming the conductive-wiring layer 31 by using a plating technique, exposure and development of the plating resist is facilitated, thereby improving the positional accuracy between the conductive-wiring layer 31 and the electrode terminals 53. The configuration wherein the seed layer 55 is formed between the electrode terminals 53 and dielectric resin layer 81 and the conductive-wiring layer 31 improves the adhesive strength between those, especially, between the electrode terminals 53 and the conductive-wiring layer 31, thereby improving the reliability of products.

Ti, W, Cr, Pt, Au, Cu, Ni, Ag, Sn and Pd are suitable for the seed layer 55, which is not limited thereto however. Upon forming the seed layer 55 and conductive-wiring layer 31, the seed layer 55 is first formed, followed by forming the plating resist pattern on the seed layer 55. Subsequently, pattern of the conductive-wiring layer 31 is formed using a plating technique in the area in which the plating resist pattern is not formed. Subsequently, the plating resist pattern is peeled off, followed by removing a portion of the seed layer 55 on which the pattern of conductive-wiring layer 31 is not formed by etching using a chemical liquid, thereby exposing the dielectric resin layer 81. The total thickness of the seed layer 55 is preferably 3 μm or smaller for prevention of reduction in the line width.

Back to FIG. 1, the conductive-wiring layer 41 has a side surface in contact with the dielectric resin layer 81, and a top surface which is not in contact with the dielectric resin layer 81. The surface of conductive-wiring layer 41 is formed at the height lower than the surface of dielectric resin layer 81. The conductive-wiring layer 41 is formed as a uniform pattern on a portion thereof that opposes the rear surface of the functional device 10.

Semi-cured resin, resin paste and Ag paste, which are referred to as dielectric attachment film, may be used for the adhesive layer 25. Due to intervention of the adhesive layer 25 between the functional device 10 and the conductive-wiring layer 41, heat can be diffused through the conductive-wiring layer 41 when the functional device 10 generates the heat, thereby improving the reliability of products. “LE-4000” (trademark) and “LE-5000” (trademark) from LINTEC Corp., and “DF402” (trademark) from Hitachi Chemical Co., Ltd. etc. are suitable for the die attachment film, which is not limited thereto however. Liquid resin including epoxy, polyimide, benzocyclobutene etc. may be used as the base material for the adhesive layer 25 instead of the die attachment film.

By forming a uniform pattern having a shape similar to the rear surface of the functional device 10, or uniform pattern having a size larger than the rear surface of the functional device 10 in a portion of the conductive-wiring layer 41 that opposes the rear surface of the functional device 10, a highly efficient heat radiation can be obtained, and at the same time, the functional device 10 can be protected against a stroke from the exterior of board, whereby a highly reliable structure can be obtained. In addition, since the conductive-wiring layer 41 is formed in a pattern as a whole, and has a portion that exposes therefrom the dielectric resin layer 81 at a suitable position, a stress occurring due to the difference in the thermal coefficient of expansion between the functional device 10 and the conductive-wiring layer 41 can be alleviated more effectively as compared to the package obtained by attaching a metal plate having a larger area, such as a heat sink, onto the rear surface of the functional device. Thus, when the circuit board is used as the package, products having a higher reliability and a longer lifetime can be obtained.

One or a plurality of metals, such as copper, nickel, gold, silver, and lead-free solder formed by a plating technique, a printing technique etc., are suitable for the conductive-wiring layers 31 and 41, which are not limited thereto however. It is possible to perform surface-mount of the electronic parts or semiconductor flip-chip bonding onto the pattern of conductive-wiring layers 31 and 41, thereby reducing the board area and the size of products while effectively assuring the area needed for the mounting. In addition, by directly mounting the electronic parts onto the conductive-wiring layer 31 disposed right above the functional device, the distance between the electronic parts and the electrode terminals 53 of the functional device 10 can be reduced, to obtain a superior high-speed electric performance.

Materials including epoxy, polyimide, liquid crystal polymer etc. as the base material are suitable for the dielectric resin layer 81, which is not limited thereto however. Resins including therein an aramid unwoven cloth, an aramid film, a glass cloth, and a silica film are preferred for improving the strength and high-speed transmission property; however, the materials to be included therein are not limited thereto.

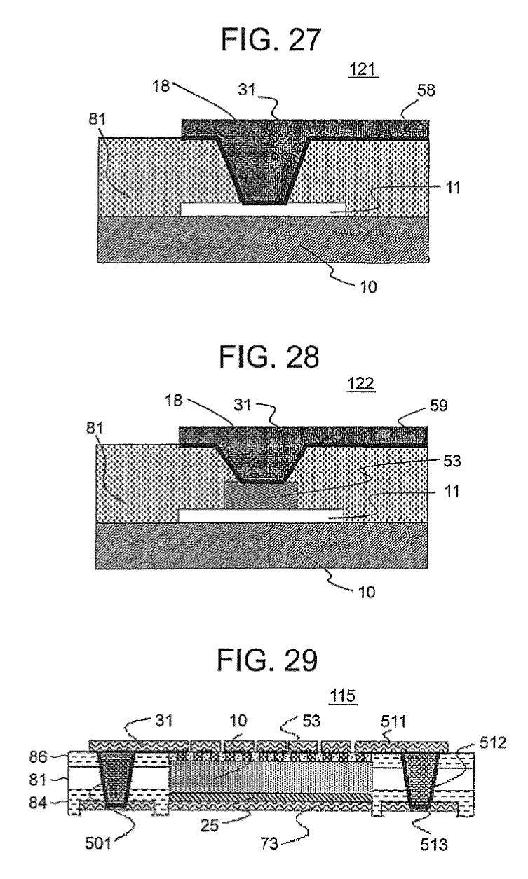

FIG. 27 is a sectional view of a circuit board according to a first comparative example of the first exemplary embodiment. In the circuit board 121, the conductive-wiring layer 31 is formed within the via-holes formed in the dielectric resin layer 81 with an intervention of the seed layer 58. In the via-holes, a via (conductor via) 18 extending from the conductive-wiring layer 31 is formed. Upon manufacturing the circuit board 121, via-holes are formed in the dielectric resin layer 81 by using CO2, or UV-YAG laser etc., and the seed layer 58 and conductive-wiring layer 31 are formed also within the through-holes. In the case of the first comparative example of FIG. 27, the laser processing is such that, although the position of the electrode pads 11 of the functional device 10 embedded in the dielectric resin layer 81 should be correctly observed, an accurate observation is difficult to achieve, if the dielectric resin layer 81 includes therein inorganic fillers or portion of the dielectric resin layer 81 existing on the functional device 10 is thick. Thus, there is a problem in that performing connection between the electrode pads 11 and the conductive-wiring layer 31 at the accurate position is difficult to achieve, thereby causing a poor product yield.

In the first comparative example of FIG. 27, the via-holes may be formed on the electrode pads 11 by using exposure and development while using a photosensitive dielectric resin layer 81. However, it is highly probable that residues of the dielectric resin layer 81 exist on the electrode pads 11 at the bottom of via-holes upon forming the seed layer 58, similarly to the case of via-holes being formed by a laser processing. For removing the residues, a chemical or mechanical desmear processing is performed, which may cause melting or structural damage of the electrode pads 11. Thus, there occurs a problem in that a reliable connection cannot be obtained between the electrode pads 11 and the conductive-wiring layer 31.

FIG. 28 is a sectional view of a circuit board according to a second comparative example of the first exemplary embodiment. The circuit board 122 differs from the circuit board 121 of FIG. 27 in that the electrode terminals 53 are formed between the electrode pads 11 and the through-holes. In the case of the second comparative example of FIG. 28, the laser processing is such that, although the position of the electrode pads 11 of the functional device 10 embedded in advance within the dielectric resin layer 81 should be correctly observed, an accurate observation is difficult to achieve, if the dielectric resin layer 81 includes therein inorganic fillers or portion of the dielectric resin layer 81 existing on the functional device 10 is thick. Thus, there occurs a problem in that performing connection between the electrode pads 11 and the conductive-wiring layer 31 at the accurate position is difficult to achieve, thereby causing a poor product yield.

In the second comparative example of FIG. 28, the via-holes may be formed on the electrode terminals 53 by exposure and development using a photosensitive dielectric resin layer 81. However, it is difficult to form the seed layer 59 having a uniform thickness within the recess configured by the via-holes due to the presence of a taper (difference in the inner diameter between the top portion and the bottom portion) of the via-holes. This causes the problem of a poor product yield and a degradation of the reliability of products.

Thus, in the present exemplary embodiment, it is determined that the electrode terminals 53 be formed in the functional device 10, the surface of dielectric resin layer 81 is planarized until the electrode terminals 53 are exposed, prior to forming the seed layer 55.

FIG. 3 is a sectional view of a circuit board according to a modified example of the first exemplary embodiment. The circuit board 101 differs from the circuit board 100 of FIGS. 1 and 2 in that another dielectric resin layer 82 is formed between the dielectric resin layer 81 and the seed layer 56. In the case where the adhesive strength between the dielectric resin layer 81 and the seed layer 56 is insufficient, the adhesive strength between the dielectric resin layer 81 and the seed layer 56 can be increased by forming a dielectric resin layer 82.

Upon forming the dielectric resin layer 82, a uniform dielectric resin layer is formed on the electrode terminals 53 and dielectric resin layer 81, and thereafter, openings for exposing therethrough the top of electrode terminals 53 are fanned. In order to form the openings having a suitable shape, a material having a superior laser workability or material having a photosensitivity is preferably used for the dielectric resin layer 82.

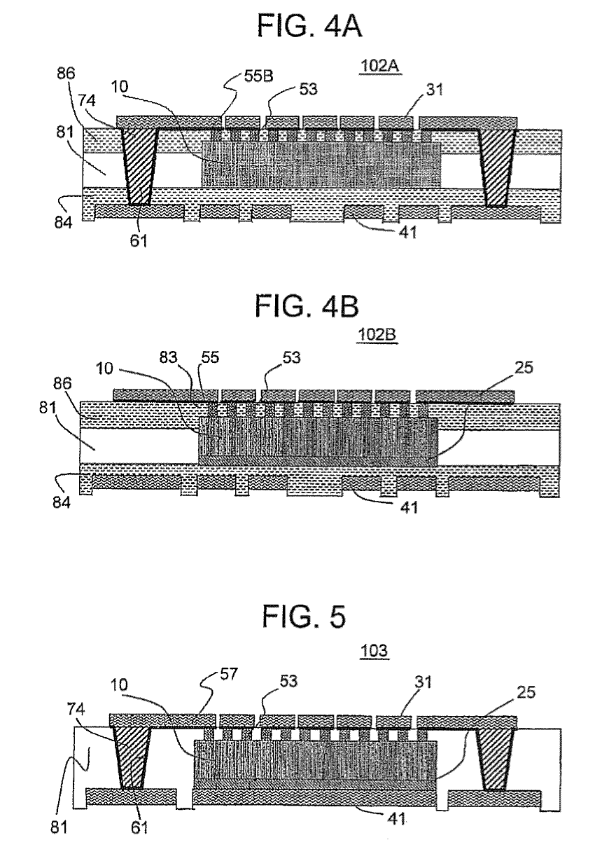

FIG. 4A is a sectional view of a second exemplary embodiment of the circuit board 102A of the present invention, and FIG. 4B is a sectional view of a circuit board according to a modified example of the second exemplary embodiment. The circuit board 102A differs from the circuit board 100 of FIG. 1 in that the rear side and front side of the functional device 10 are configured by dielectric resin layers 84 and 11 different from the dielectric resin layer 81, in that via-holes 61 that penetrate the dielectric resin layers 81, 84 and 85 and connect to the conductive-wiring layers 31 and 41 are formed and via-plugs 74 are formed by filling via-holes 61 with a metal or conductive paste, and in that the functional device 10 is directly bonded onto the dielectric resin layer 84 without an intervention of the adhesive layer 25. On the other hand, the circuit board 102B differs from the circuit board 100 of FIG. 1 in that the rear side and front side of the functional device 10 are configured by dielectric resin layers 84 and 11 different from the dielectric resin layer 81. In the circuit board 102B, the dielectric resin layer 84 is formed also between the adhesive layer 25 and the conductive-wiring layer 41. A soft resin is used for the dielectric resin layers 84 and 11 that are near the front surface and rear surface of the circuit board, for suppressing occurrence of cracks caused by an external bending stress, whereas a resin having a thermal coefficient of expansion similar to that of the functional device 10 is used for suppressing occurrence of cracks caused by a difference in the thermal coefficient of expansion between the dielectric resin layer 81 and the functional device 10. The via-holes 61 are formed to have a smaller diameter toward the bottom side and have a specific taper angle. The seed layer 57 extends on the side surface as well as the bottom surface of the via-holes 61.

Due to the use of separate dielectric resin layers, it is possible to use a combination of resins having a higher temperature resistance and a lower temperature resistance, or a combination of an expensive resin and an inexpensive resin, thereby achieving improvement in the reliability of products and a lower cost. In addition, if a dielectric resin layer 83 is formed on the circumference of the electrode terminals 53 of the functional device 10, for example, a resin having a superior adhesiveness with respect to the dielectric resin layer 83 can be selected for the dielectric resin layer 86. The electrode terminals 53, if exposed from the dielectric resin layer 83, can be clearly observed as an alignment mark, to thereby improve the mounting accuracy. On the other hand, if the electrode terminals 53 are embedded within the dielectric resin layer 83, the advantage of surface protection as well as improvement of workability during mounting of the functional device can be obtained. Note that the functional device 10 may be covered by the dielectric resin layer 86 without forming the dielectric resin layer 83 to achieve a cost reduction. The number of dielectric resin layers in the combination is not limited to three.

In the circuit boards 102A and 102B, a pattern is formed also in a portion of the conductive-wiring layer 41 that opposes the rear surface of the functional device 10. By forming the pattern of conductive-wiring layer 41 also directly under the functional device 1, it is possible to perform surface-mounting of electronic parts and bonding of semiconductor flip-chip etc. onto this pattern, thereby increasing the area for mounting and reducing the size of products. Since the dielectric resin layer 84 itself is a resin in the circuit board 102A, the surface of functional device 10 opposite to the electrode terminals 53 is pressed for mounting thereof against the dielectric resin layer 84 while applying heat in a semi-cured state thereof prior to curing, whereby the dielectric resin layer 84 increases the fluidity thereof due to the heat, and closely adheres onto the functional device 10. This obviates an adhesive layer 25 having a thickness of about 2 to 40 μm, to thereby reduce the thickness of the circuit board. Description with respect to the via-holes 61, via-plugs 74 and seed layer 57 is omitted herein for avoiding duplication with the description on the circuit board shown in FIG. 5.

FIG. 5 is a sectional view of a third exemplary embodiment of the circuit board of the present invention. The circuit board 103 differs from the circuit board 100 of FIG. 1 in that the via-holes 61 that penetrate the dielectric resin layer 81 and connect to the conductive-wiring layers 31 and 41 are formed, and the via-plugs 74 are formed by filling the via-holes 61 with a metal or conductive paste. The via-holes 61 are formed to have a smaller diameter toward the bottom side thereof and have a specific taper angle. The seed layer 57 extends on the side surface and bottom surface of the via-holes 61.

Upon forming the via-plugs 74, formation of the conductive-wiring layer 31 may be performed in parallel. Formation of the conductive-wiring layers 31 and 41 and via-plugs 74 after forming the seed layer 57 may preferably use one or a plurality of metals, such as copper, nickel, gold, silver and lead-free solder, without limitation thereto. All the via-holes 61 have the same taper angle, which case facilitates observation of the plated portion in the step of metal plating of the via-holes 61, thereby facilitating judgment of a non-defective plated state or defective portion to improve the quality of products. If the ratio of height to diameter of the via-holes 61 is larger than one, lead-fire solder paste or conductive paste may be used to fill the same by using a printing technique after forming the seed layer 57.

Connection between the conductive-wiring layer 31 on the front side and the conductive-wiring layer 41 on the rear side of the circuit board 41 through the via-plugs 74 with a shortest distance improves the high-speed electric performance up to about 1 GHz or higher between the functional device 10 and the electronic parts mounted on the front and rear sides of the circuit board. Since the conductive-wiring layer 31 and the conductive-wiring layers 41 are connected together through the via-plugs 74, it is possible to stack circuit boards in the vertical direction, to thereby achieve a high-density mounted body. Due to extension of the seed layer 57 on the side surface and bottom surface of the via-holes 61, the adhesive strength between the via-plugs 74 and the conductive-wiring layer 41 is increased, to thereby improve the reliability of products.

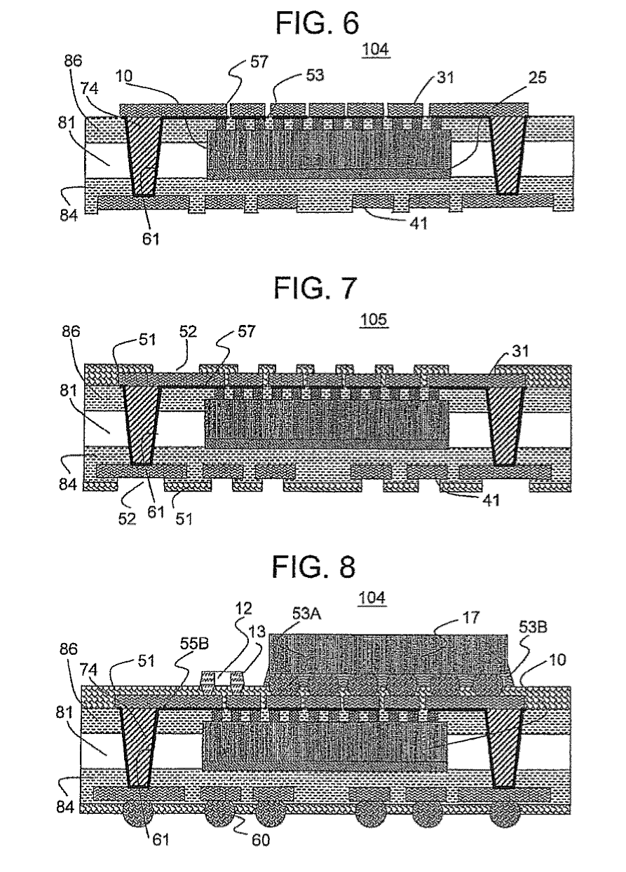

FIG. 6 is a sectional view of a circuit board according to a first modified example of the third exemplary embodiment. The circuit board 104 differs from the circuit board 103 of FIG. 5 in that the front and rear sides of the functional device 10 are configured by the dielectric resin layers 84 and 11 different from the dielectric resin layer 81, similarly to the circuit boards 102A and 102B of FIG. 4A and FIG. 4B.

FIG. 7 is a sectional view of a circuit board according to a second modified example of the third exemplary embodiment. The circuit board 105 differs from the circuit board 104 of FIG. 6 in that a solder resist layer 51 is formed on the front surface and mar surface thereof. Openings 52 that expose therefrom the electrode portion are formed in the solder resist layer 51. Upon forming the solder resist layer 51 having the openings 52, a solder resist layer is supplied onto the front surface and rear surface of the circuit board by a printing technique, followed by exposure and development thereof. The circuit board 104 may be used as a BGA (ball grid array) package after mounting solder bumps 53 within the openings 52, as shown in FIG. 8, without any limitation as to the shape of package and the electronic parts connected to the openings 52.

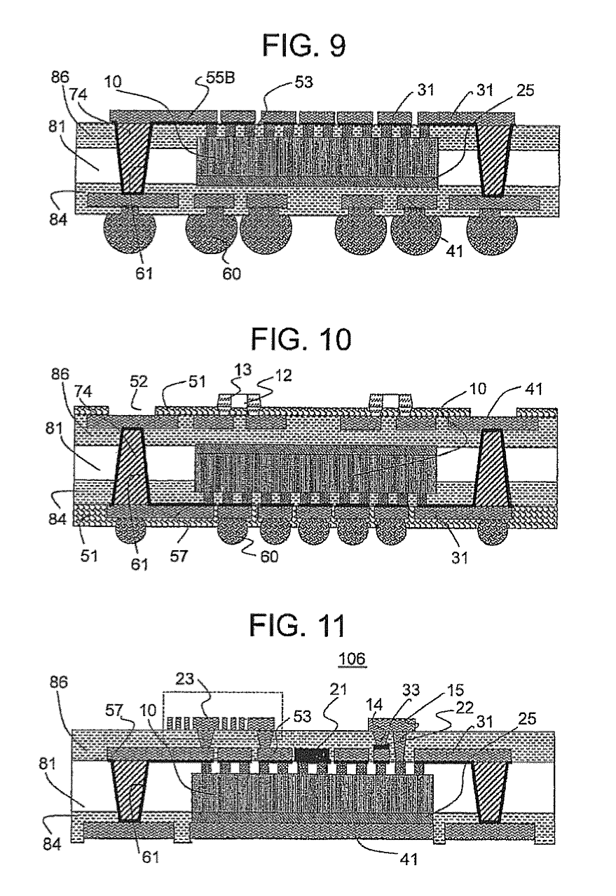

On the surface of the conductive-wiring layer 31, it is needed to prevent a short-circuit failure caused by reflow of the lead-free solder or melting of the solder balls 60 upon mounting the electronic parts 12 and functional device 17, such as a second LSI and radio elements, shown in FIG. 8, and thus formation of the solder resist layer 51 is needed. On the other hand, since the surface of conductive-wiring layer 41 is formed at a height lower than the surface of dielectric resin layer 84, as shown in FIG. 9, it is also possible to form solder balls 60 directly on the conductive-wiring layer 41, without forming the solder resist layer 51. However, if the substrate has a smaller thickness, it is preferred to form the solder resist layer 51 also on the surface of conductive-wiring layer 41 for prevention of warp of the board, to thereby maintain the symmetry of the structure between the front side and the rear side of the board.

It is possible to form solder balls 60 on the conductive-wiring layer 31, as shown in FIG. 10 and contrary to FIG. 8, and the BGA package thus formed is then mounted on another circuit board, such as a mother board, with an intervention of the solder balls 60. In this case, it is possible to reduce the line length between the electrode terminals 53 of the functional device 10 and the circuit board, whereby products having an excellent high-speed electric performance can be obtained. The electronic parts 12 may be provided within a receiving hole formed in the circuit board.

FIG. 11 is a sectional view of a fourth exemplary embodiment of the circuit board of the present invention. The circuit board 106 differs from the circuit board 104 shown in FIG. 6 in that resistors 21, dielectric elements 22 and inductors 23 are formed therein. The resistors 21 are formed as a part of the conductive-wiring layer 31, and include at least one species of element of Cu, W, Cr, Pt, Ni, Zn, Fe, Al, C, Mn, Ir, Ti, N and O. The resistors 21 may be formed in a conductive-wiring layer 33 that is located at one layer above the conductive-wiring layer 31.

The dielectric elements 22 are formed between the conductive-wiring layer 31 and the vias 15.1 that connect together the conductive-wiring layer 31 and the conductive-wiring layer 31, and include one or more element of Mg, Ti, Sr, Ba, Ca, Zn, Al, Ta, Si, Au, N and O. The inductors 23 are formed as the same layer as the conductive-wiring layer 33, and have a spiral shape or meander shape. In the present exemplary embodiment, another seed layer other than the seed layer 57 may be provided on the bottom of the via 152, the another seed layer connecting the conductive-wiring layer 33 to the electrode terminals 53 of the functional device 10. These resistors 21, dielectric elements 22, and inductors 23 may be fanned on the rear side of the functional device 10.

In the present exemplary embodiment, inclusion of any one of the above resistors 21, dielectric elements 22, and inductors 23 can reduce the volume of the passive component embedded in or surface-mounted on the circuit board, thereby achieving a superior electric performance. Provision of a plurality of conductive-wiring layers on the front side of the functional device achieves a circuit board having a higher function. The solder resist layer may be formed on the front surface and rear surface of the circuit board.

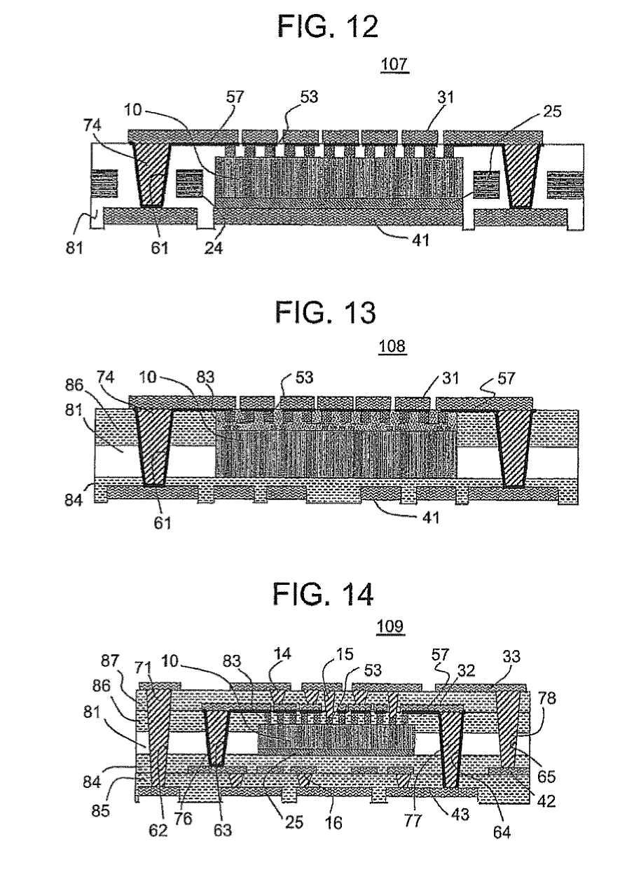

FIG. 12 is a sectional view of a fifth exemplary embodiment of the circuit baud of the present invention. The circuit board 107 differs from the circuit board 103 shown in FIG. 5 in that a metal or ceramic intermediate layer 24 is formed adjacent to the side of functional device 10. The intermediate layer 24 provides a strength to the circuit board. Thus, if the circuit board has a smaller thickness, the reliability of products can be effectively improved. In addition, the intermediate layer 24 may be comprised of a metal, connected to conductive-wiring layers 31 and 41 through vias, and used as a ground layer to achieve a superior electric property. If the functional device 10 has a higher calorific powder, the intermediate layer 24 may be comprised of a metal to improve the heat radiation capability.

If the conductive-wiring layer is formed on the front and rear surfaces of the intermediate layer 24, the circuit board may have a larger number of layers to achieve a highly efficient multilevel-wiring board. The solder resist layer may be formed on the front surface and rear surface of the circuit board.

FIG. 13 is a sectional view of a sixth exemplary embodiment of the circuit board of the present invention. The circuit board 108 differs from the circuit board 104 of FIG. 6 in that the functional device 10 is directly bonded onto the dielectric resin layer 84 without an intervention of the adhesive layer 25, and in that the electrode terminals 53 are formed therein with an intervention of cylindrical copper referred to as copper post, which is formed within the dielectric resin layer 83, and at least one conductive-wiring layer.

Since the dielectric resin layer 84 itself is a resin, if the surface of functional device 10 opposing the electrode terminals 53 is pressed against the dielectric resin layer 84 in a semi-cured state thereof prior to curing, while applying heat thereto, the dielectric resin layer 84 increases the fluidity due to the heat and closely adheres onto the functional device 10. This obviates the adhesive layer 25 having a thickness of about 2 to 40 μm, to achieve a reduction in the thickness of the circuit board. Note that the shape or material of the copper posts and conductive-wiring layer is not limited. If it is desired to fix the functional device with a strength higher than the strength with which the dielectric resin layer 84 fixes the functional device, the adhesive layer 25 may be used, as shown in FIG. 6.

FIG. 14 is a sectional view of a seventh exemplary embodiment of the circuit board of the present invention. The circuit board 109 differs from the circuit board 104 of FIG. 6 in that two conductive-wiring layers 32 and 33 are formed on the front side of the functional device 10 with an intervention of a dielectric resin layer 87, in that two conductive-wiring layers 42 and 43 are formed on the rear side of the functional device 10 with an intervention of the dielectric resin layer 84.1, and in that via-plugs 75 to 78 and 14 to 16 that connect together the electrode terminals 53, conductive-wiring layers 32 and 33 and conductive-wiring layers 42 and 43 are formed.

Via-plugs 75 connect together the conductive-wiring layer 33 and the conductive-wiring layer 43, via-plugs 76 connects together the conductive-wiring layer 32 and the conductive-wiring layer 42, via-plugs 77 connects together the conductive-wiring layer 32 and the conductive-wiring layer 43, and via-plugs 78 connect together the conductive-wiring layer 33 and the conductive-wiring layer 42. Via-plugs 14 connect together the conductive-wiring layer 32 and the conductive-wiring layer 33, via-plugs 15 connect together the electrode terminals 53 and the conductive-wiring layer 33, and via-plugs 16 connect together the conductive-wiring layer 42 and the conductive-wiring layer 43. The via-plugs 75 to 78 are comprised of a plating metal, such as copper, nickel, gold and silver, or conductive paste.

Since the via-plugs 75 to 78 connect each conductive-wiring layer to any arbitrary conductive-wiring layer, the design choice of the circuitry is increased. Since the via-plugs 15 connect together the electrode terminals 53 and the conductive-wiring layer 33, the line distance between the electrode terminals 53 of the functional device 10 and the capacitors or semiconductor devices formed outside the circuit board can be reduced. The seed layer 57 is formed between the electrode terminals 53 and conductive-wiring layer 32 and the dielectric resin layer 86 as well as on the side surface and bottom surface of the via-holes 63 and 64.

The surface of the conductive-wiring layer 42 is formed at the same height as the surface of dielectric resin layer 84. As for the conductive-wiring layer 43, the side surface thereof contacts the dielectric resin layer 84.1, and the dielectric resin layer 84.1 is not formed on the top surface thereof. The top surface of the conductive-wiring layer 43 is formed at a height lower than the surface of dielectric resin layer 84.1.

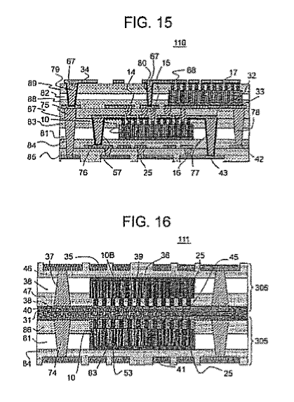

FIG. 15 is a sectional view of a circuit board according to a modified example of the seventh exemplary embodiment. The circuit board 110 differs from the circuit board 109 of FIG. 14 in that a functional device 17 is disposed on the conductive-wiring layer 33 with an intervention of the adhesive layer 25. The functional device 17 is covered by dielectric resin layers 87, 88 and 89, and the conductive-wiring layer 34 is formed on the top surface of the dielectric resin layer 89. The conductive-wiring layer 33 and the conductive-wiring layer 34 are connected together by via-plugs 79 and 80. The plating seed layer 57 is formed between the electrode terminals 53 of the functional device 17 and dielectric resin layer 89 and the conductive-wiring layer 34, and on the top surface and bottom surface of the via-holes 66 and 67.

Incorporation of a plurality of functional devices 10 and 17 reduces the line length between the embedded functional devices 10 and 17, to achieve a circuit board that is superior in the high-speed electric performance. A circuit board having a variety of functions is realized by combining radio elements with elements of logic and memory devices, as the functional devices 10 and 17. Since the functional devices 10 and 17 are not exposed on the surface, workability can be improved during the conveyance.

FIG. 16 is a sectional view of an eighth exemplary embodiment of the circuit board of the present invention. The circuit board 111 is such that circuit boards 305 and 306 embedding therein functional devices 10 and 10B, respectively, such as shown in FIG. 6, are stacked one on another in a thickness direction with an intervention of an adhesive layer 40 and conductive paste 45. Epoxy, polyimide, liquid crystal polymer etc. used as the base are preferable for the adhesive layer 40, which is not limited thereto however. A resin including therein an aramid unwoven cloth, an aramid film, a glass cloth, and a silica film is preferred for the adhesive layer 40, for the purpose of improvement in the strength or high-speed transmission property, although the materials to be included therein are not limited thereto.

Since the electrode terminals 53 of the functional device 10 oppose those of the functional device 10B, the line length between the functional devices 10 and 10B is reduced, to achieve a circuit board superior in the high-speed electric performance. Since the distance between the surface of the functional devices 10 and 10B and the surface of the circuit boards 305 and 306 is equal between the circuit board 305 and the circuit board 306, if a flip-chip bonding is performed with respect to the LSI, for example, the line distance between the LSI and the electrode terminals 53 of both the functional devices 10 and 10B is equal between the circuit board 305 and the circuit board 306, thereby improving the connection reliability. Although the circuit boards 305 and 306, such as shown in FIG. 6, are connected together in the present exemplary embodiment, one of the circuit boards, e.g. circuit board 305, may be replaced by another multilevel wiring board for connection. Both the circuit boards 305 and 306 may have different sizes in the outer shape.

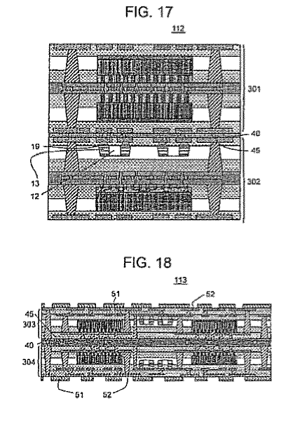

FIG. 17 is a sectional view of a circuit board according to a first modified example of the eighth exemplary embodiment. The circuit board 112 is such that circuit boards 301 and 302, such as shown in FIG. 16, are stacked one on another in a thickness direction with an intervention of the adhesive layer 40 and conductive paste 45. FIG. 18 is a sectional view of a circuit board according to a second modified example of the eighth exemplary embodiment. The circuit board 113 is such that circuit boards 303 and 304 mounting thereon a plurality of functional devices that are arranged in the horizontal direction are stacked one on another in the thickness direction with an intervention of the adhesive layer 40 and conductive paste 45. The solder resist layer 51 having therein openings 52 is provided on both the front and rear surfaces of the circuit board. Since the circuit board includes a plurality of embedded functional devices which are integrated three-dimensionally, the line length between the functional devices can be reduced.

FIG. 19 is a top plan view of a ninth exemplary embodiment of the circuit board of the present invention. The circuit board 114 is such that an area of the circuit board 109 shown in FIG. 14, for example, wherein the electrode terminals 53 and 54 do not exist and pattern of the conductive-wiring layer 31 is not formed is provided with the conductive-wiring layer 34 that is uniformly formed. The electrode terminals 54 are ones that are connected to the conductive-wiring layer 33 through the vias 15.2. The conductive-wiring layer 34 is formed to connect together the top portion of the functional device 10A except for the top portion of the electrode terminals 54 and the circumferential area of the functional device 10A. Numeral 19 denotes the outline of the functional device 10A.

The structure of connection between the exposed surface of the electrode terminals 53 and the conductive-wiring layer 31 may be such that the conductive-wiring layer 31 exists only right above a portion of the exposed surface of the circular electrode terminals 53, as shown in FIG. 19, or a land is formed on the conductive-wiring layer 31 so as to cover the entire exposed surface of the electrode terminals 53, although the shape is not limited thereto. The conductive-wiring layer 34 has the advantage of preventing the embedded functional device 10A from being damaged by a stress caused by a bend or stroke. The conductive-wiring layer 34 may be electrically used as the wound, and has an electromagnetic shield effect, to provide superior electric properties to the products. The conductive-wiring layer 34 may be connected to the electrode terminals 53 configuring the ground of the functional device 10A.

FIG. 29 is a sectional view of a tenth exemplary embodiment of the circuit board of the present invention. In the circuit board 115, the functional device 10 is fixed onto the conductive-wiring layer 73 with an intervention of the adhesive layer 25 and embedded within a plurality of dielectric resin layers 81, 84 and 85. The conductor vias 501 that connect together the conductive-wiring layer 31 and the conductive-wiring layer 73 are formed on the side of functional device 10. The seed layers 512, 513 and 511 are formed on the side surface, bottom portion and the top portion, respectively, of the vias 501, to thereby enhance the adhesion strength with respect to the dielectric resin layer and adhesion strength with respect to the conductive-wiring layer 31. Here, the vias 501 are filled vias wherein a conductor is embedded. A seed layer 511 is formed also between the electrode terminals 53 of the embedded functional device 10 and the conductive-wiring layer 31 that are embedded at the same time.

In the present exemplary embodiment, provision of the seed layer on the side surface, bottom portion and top portion of the vias prevents internal fracture of the vias, fracture of top portion and bottom portion of the vias, peel-off of the side surface of the vias from the dielectric resin layer, in the event of deformation caused by incorporation of the functional device in the board, thereby achieving highly reliable products. Forming a common layer for the electrode terminals 53 and seed layer 511 facilitates observation of the position during the resist exposure upon forming the wiring pattern of the vias 501 and electrode terminals 53, to obtain a superior positioning accuracy. Thus, the product yield can be improved. In addition, use of the filled vias as the vias 501 reduces the electric resistance to thereby improve the electric properties as compared to the case of using conformal-type ones.

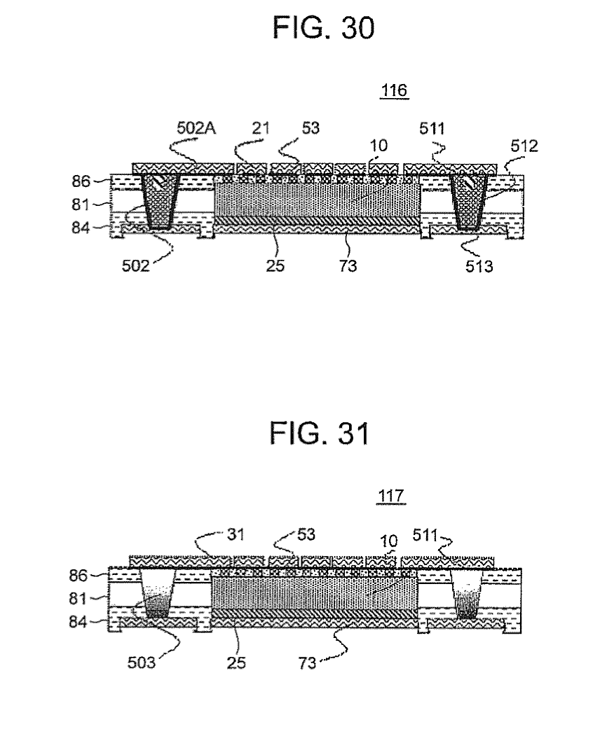

FIG. 30 is a sectional view of a circuit board according to a first modified example of the tenth exemplary embodiment. The circuit board 116 differs from the circuit board 115 of FIG. 29 in that conformal-type vias 502 formed by plating of a conductor layer only onto the side surface and bottom portion of the vias are used herein, whereas the vias shown in FIG. 29 are the filled-type ones. Resin 502A is embedded in the vicinity of the center of the vias 502 located on the side of conductive-wiring layer 31. The seed layers 512, 513 and 511 are formed on the side surface, bottom portion and top portion, respectively, of the vias 502 including therein the resin 502A, thereby increasing the adhesive strength with respect to the insulator resin and conductive-wiring layer 31.

In the present exemplary embodiment, internal fracture of the vias, fracture of the top and bottom portions of the vias and peel-off of the side surface of the vias from the resin layer can be prevented even in the event of deformation of the board caused by incorporation of the functional device 10 in the board, similarly to the circuit board 115 shown in FIG. 29, whereby products having a higher reliability can be achieved. Forming the electrode terminals 53 and seed layer 511 as a common layer facilitates positional observation during resist exposure upon forming the wiring pattern of vias 502 and electrode terminals 53, thereby providing a superior positioning accuracy. Thus, the product yield can be improved. Due to the resin 502A embedded within the vias 502, it is possible to allow the thermal coefficient of expansion of vias 502 to be close to that of the dielectric resin layer existing outside of the vias 502, to thereby improve the reliability.

FIG. 31 is a sectional view of an eleventh exemplary embodiment of the circuit board of the present invention. In the circuit board 117, the functional device 10 is fixed onto the conductive-wiring layer 73 with an intervention of the adhesive layer 25, and is embedded within a plurality of dielectric resin layers 81, 84 and 85. Conductor vias 503 that connect together the conductive-wiring layer 31 and the conductive-wiring layer 73 are formed on the side of functional device 10. Although the seed layer is not formed on the side surface and bottom portion of the vias 503, the seed layer 511 is formed on the top portion thereof to enhance the adhesive strength with respect to the conductive-wiring layer 31. Here, the vias 503 are filled ones filled with a conductor, wherein the crystal grains of the conductor structure are dense at the bottom portion near the conductive-wiring layer 73, and the diameter of the crystal grains is larger at the top portion thereof near the conductive-wiring layer 31 as compared to the bottom portion thereof.

As a result, in the present exemplary embodiment, a portion of the internal conductor of vias 503 near the conductive-wiring layer 31 and having a large inner diameter may be of a material having a larger crystal-grain diameter and an expanding property, whereby the stress can be alleviated in the event of deformation of the substrate, such as warp of the board caused by embedding the functional device 10. On the other hand, although the internal conductor material of the vias 503 in the vicinity of the conductive-wiring layer 73 and having a smaller inner diameter and a smaller contact area does not have an expanding property, a superior adhesive strength can be obtained with respect to the conductive-wiring layer 73. Therefore, even if the seed layer is not formed at the interface between the side surface of the vias and the dielectric resin layer, disconnection of vias can be avoided by alleviating the stress applied to the interface, thereby improving the reliability of products.

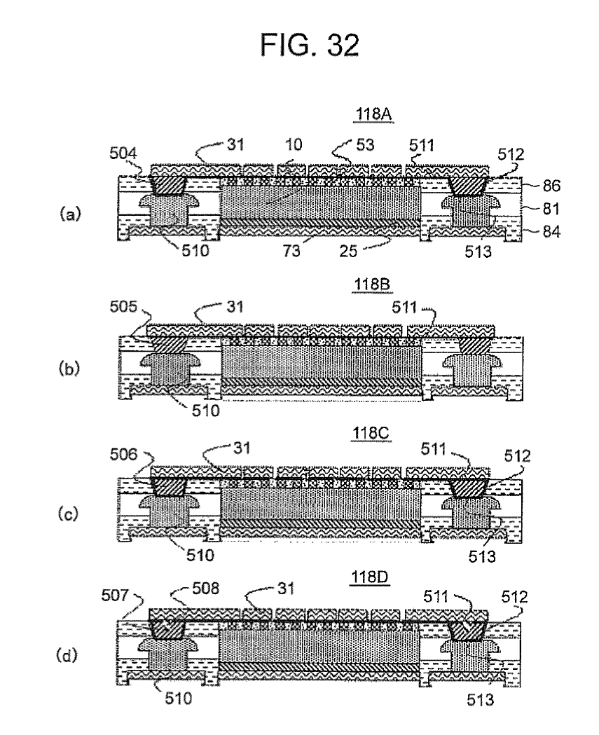

FIGS. 32(a), 32(b), 32(c) and 32(d) are sectional views of twelfth exemplary embodiments of the circuit board of the present invention. In the circuit boards 118A to 118D, conductor vias that connect together the conductive-wiring layer 31 and the conductive-wiring layer 73 include mushroom-shaped posts (conductor posts) 510 and via-plugs 504, 505, 506 and 507 connected to the mushroom-shaped posts 510. The mushroom-shaped posts 510 have a portion of a substantially uniform diameter, and a large-diameter portion (corresponding to pileus and also referred to as pileus-structured portion) having a larger diameter than the uniform-diameter portion, and are disposed near the conductive-wiring layer 73, as shown in the figure. This pileus-structured portion inserts a wedge onto the dielectric resin layer in the horizontal direction of the board. Laser vias are formed on the mushroom-shaped posts 510 near the conductive-wiring layer 31.

In the circuit board 118A, as shown in FIG. 32(a), the via-plugs 504 are formed, seed layers 513 and 512 are formed on the bottom portion and side surface, respectively, thereof, and a common seed layer 511 is formed from the upper portion of side surface of the via-plugs 504 through the bottom portion of the conductive-wiring layer 31 toward the electrode terminals 53 and conductive-wiring layer 31. The seed layers 511, 512 and 513 are formed in succession. The via-plugs 504 may be filled-type ones as well as conformal-type ones. In the circuit board 118B, as shown in FIG. 32(b), via-plugs 505 are formed, and the seed layer 511 thereof common to the electrode terminals 53 is formed only on the top portion of the via-plugs 505 between the same and the conductive-wiring layer 31. In the circuit board 118C, as shown in FIG. 32(c), via-plugs 506 are formed, and seed layer 513, 512 and 511 are formed on the bottom portion, side surface and top portion, respectively, of the via-plugs, whereby reliability of strength in the structure of incorporation of the functional device 10 is improved. In the circuit board 118D, as shown in FIG. 32(d), via-plugs 507 including therein embedded resin 508 are formed for the case of the via-plugs being conformal-type ones, the seed layers 513 and 512 are formed on the bottom portion and side surface, respectively, of the via-plugs 507, and the seed layer 511 is also formed on the top portion thereof.

In the present exemplary embodiment, the above pileus-structured portion of the mushroom-shaped posts 510 extends as a wedge within the dielectric resin layer in the horizontal direction (direction substantially perpendicular to the thickness direction) of the dielectric resin layer, whereby the strength between the vias and the dielectric resin layer in the thickness direction can be improved, even without forming the seed layer on the side surface of the vias, for the case of thickness deformation or warping stress occurring in the functional-device-embedded board, to thereby prevent disconnection at the vias. Thus, reliability of products can be improved. On the other hand, for the ordinary vias having a sectional shape of trapezoid, there is a possibility that the via conductor is peeled off from the contacting dielectric resin layer, if reinforcement of adhesion of the side surface of the vias is not employed with respect to the dielectric resin layer by using the seed layer, as in the case of the present exemplary embodiment. Note that circuit boards 118A to 118D may be selected as desired in consideration of the cost of materials and the combination with respect to the materials of the via-plugs 504 to 507. Irrespective of selection of any of those, these circuit boards have a higher reliability, compared to the circuit board without using the mushroom-shaped posts 510, because of using the mushroom-shaped posts 510.

### (Manufacturing Process of Circuit Board)

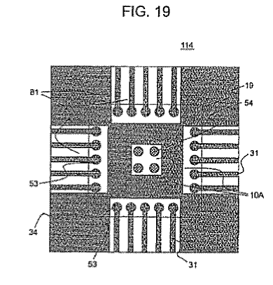

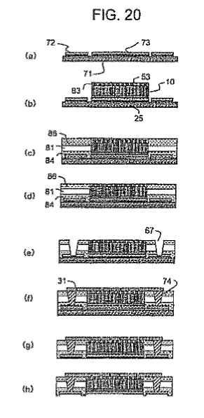

FIGS. 20(a) to 20(h) are sectional views of respective fabrication stages in a first exemplary embodiment of the circuit-board manufacturing process of the present invention. First, as shown in FIG. 20(a), a plating resist is supplied onto the supporting substrate 71, and subjected to exposure and development thereof, followed by plating the pattern of conductive-wiring layer 72 by using a plating technique. At this stage, it is preferable that the conductive-wiring layer 72 be not solved by the etching solution, and be comprised of a material different from the supporting substrate 71, if the supporting substrate 71 is of a metal and the etching is to remove the supporting substrate 71. Since the conductive-wiring layer 72 is the metal exposed on the surface after etching the supporting substrate 71, gold and solder are preferably used for the metal to be plated, which is not limited thereto. The conductive-wiring layer 72 may be comprised of a plurality of species of plating layers instead of a single plating layer.

A single material, such as Si, glass, aluminum, stainless steel, polyimide, epoxy, or a composite material thereof is preferably used for the supporting substrate 71, which is not limited thereto however. If the supporting substrate 71 is not a conductor material, provision of a plating seed metal by using sputtering or electroless plating allows formation of the conductive-wiring layer 72. If the supporting substrate 71 is removed by a process other than the etching, provision of a releasing material in advance within the material of the supporting substrate 71 is preferred, without limitation thereto. For example, as a releasing layer adhered onto a plate comprised of a single material, such as Si, glass, aluminum, stainless steel, polyimide and epoxy, an ultra thin copper foil with a career, “Micro Thin (MT)” series, including a releasing layer sandwiched between two copper foils and supplied from Mitsui Mining and Smelting Co., Ltd. may be preferably used, and a single-surface releasing tape, “PTFE tape”, supplied form Sumitomo 3M Co. Ltd may be preferably used for the supporting substrate 71. The supporting substrate 71 including a compound material is not limited thereto however.

Subsequently, the conductive-wiring layer 73 is formed to have a predetermined thickness by using a plating technique, without peeling off the plating resist or after peeling off the plating resist and forming another resist pattern, and thereafter the plating resist is peeled off. At this stage, it is preferable that the conductive-wiring layer 73 exist on the conductive-wiring layer 72. Thus, gold, copper, nickel etc. are preferably used, without limitation thereto, for the conductive-wiring layer 73 which is left after removal of the supporting substrate 72. In a subsequent step, as shown in FIG. 20(b), the functional device 10 is mounted on the conductive-wiring layer 73 with an intervention of the adhesive layer 25 while applying heat and pressure.

At this stage, it is preferable to form the pattern of conductive-wiring layer 73 in the area for mounting thereon the device so that a planar metal area is obtained, because the area functions as a heat sink after removal of the supporting substrate 71, without limitation thereto. The functional device 10 is provided in advance with electrode terminals 53 having a cylindrical shape or multilevel wiring structure, or in an alternative, may use Au stud bumps, although the configuration of the electrode terminals 53 is not limited thereto. Materials of the electrode terminals 53 include Cu, Ag, Ni etc., without limitation thereto. If protection of the chip active surface is needed, the dielectric resin layer 83 is provided; however, if there is little problem in the strength, it may be obviated. If the dielectric resin layer 83 is provided, the electrode terminals 53 of the functional device may be embedded, prior to the mounting, within the dielectric resin layer 83 and without being exposed on the surface.

In a subsequent step, as shown in FIG. 20(c), dielectric resin layers 81 and 85 are supplied onto the side of electrode terminals 53 of the functional device 10. The process for feeding the resin may preferably use a vacuum laminating technique, a vacuum pressing etc., but not limited thereto. Upon supplying the dielectric resin layer 81 onto the conductive-wiring layer 73 or supporting substrate 71, it is possible to increase the adhesive strength with respect to the dielectric resin layers 81 by roughening the surface of the conductive-wiring layer 73 or supporting substrate 71. For preventing the circuit board from being warped at the stage after removing the supporting substrate 71, a suitable combination of dielectric resin layers and a suitable order of deposition of the dielectric resin layers is selected. If the dielectric resin layer 81 disposed on the side surface of the functional device 10 includes a non-fluidity substance, such as glass cloth and aramid film, a space equivalent to or somewhat larger than the outer shape of the functional device is provided within the dielectric resin layer 81, for preventing the functional device 10 from being damaged by the non-fluidity substance in the dielectric resin layer 81 during pressing.

The number and species of the dielectric resin layers may be judged as desired depending on the thickness of the embedded functional device 10 and the overall thickness of the board, and a single layer may be used. In a subsequent step, as shown in FIG. 20(d), electrode terminals 53 are exposed on the surface by using a grinding device, a buff-polishing device etc. The surface height of the electrode terminals 53 exposed on the surface at this stage is the same as that of the surrounding dielectric resin layer 86. A range of variation of the height that is 20 μm or less, if it occurs depending on the roughness of the whetstone or buffing material used for grinding at this stage, is well within the scope of the present invention.

Thereafter, as shown in FIG. 20(e), via-holes 67 are formed to reach any arbitrary conductive-wiring layer 73 in the vicinity of the supporting substrate 71 by using a laser equipment, such as CO2 laser and UV-YAG laser. In the present invention, at this stage, due to grinding the alignment mark as well as the electrode terminals 53 in the step of FIG. 20(d), an excellent positional accuracy can be obtained in the laser processing, thereby improving the yield during manufacturing the products. If the vias are not formed, the conductive-wiring layers 31 and 73 on the top and bottom of the functional device 10 are not connected together in the subsequent electroless plating or electrolytic plating. However, the conductive-wiring layer 73 provides the advantage of heat radiation and protection of the functional device 10, whereas the conductive-wiring layer 31 expands the wiring rule of the electrode terminals 53, which may be used as external terminals.

After forming the via-holes 67 in the dielectric resin layers 81 and 85, resin residues within the via-holes 67 are removed by a desmear processing, and at the same time the grinding sludge configured by resin residues existing on the portion of the electrode terminals 53 exposed on the surface can also be removed. The surface of dielectric resin layer 86 has thereon concaves and convexes of 10-μm height or less due to the desmear processing, which have an anchor effect to improve the adhesive strength after forming the conductive-wiring layer 31.

After washing the conductive-wiring layer 73 by using a weak acid, such as dilute sulfuric acid, at least one conductor layer is formed by an electroless plating using copper, nickel etc. or by a sputtering processing using at least one species of element in the group consisting of Ti, W, Cr, Pt, Au, Cu, Ni, Ag, Sn and Pd, and used as the seed layer for subsequent plating step. The technique for forming the seed layer is not limited to the electroless plating or sputtering processing. In a subsequent step; as shown in FIG. 20(f), a plating resist layer is formed, the conductive-wiring layer 31 is formed, the inside of via-holes 67 is plated by a metal, thereafter the plating resist is removed, and the plating seed layer other than for the conductive-wiring layer is etched. At this stage, the vias formed in the via-holes 67 may be filled vias wherein the entire via-holes are filled with a metal or conformal-type vias wherein only the sidewall of the via-holes is plated. In addition, the vias may be obtained by embedding conductive paste by using a printing technique, and thereafter plating the top portion of the vias simultaneously with formation of the conductive-wiring layer 31, without limitation to this process.

In a subsequent step, as shown in FIG. 20(g), the supporting substrate 71 is removed by etching, polishing or peeling off to expose the conductive-wiring layer 72. At this stage, the height of the conductive-wiring layer 72 is the same as the height of the dielectric resin layer 84 that encircles the circumference. Although this may be used as it is, the conductive-wiring layer 72 may be etched using a chemical liquid in the subsequent step, as shown in FIG. 20(h), to expose the conductive-wiring layer 73 on the surface. At this stage, the height of the conductive-wiring layer 73 is lower than that of the dielectric resin layer 84 that encircles the circumference, whereby the dielectric resin layer 84 can function as the solder resist layer. The conductive-wiring layers 72 and 73 are wiring layers which are consecutively formed on the supporting substrate 71, and on which the intervening dielectric resin layer is not provided, allowing the circuit board to achieve a higher-reliability mounting.

The conductive-wiring layers 72 and 73, which are originally formed on the supporting substrate 71, have a uniform height, are located on the same plane, and can be preferably used as electrode terminals by which the surface mounting is performed in the semiconductor device, BGA package etc., to achieve a high connection reliability. The circuit board thus obtained may be used in this state, or may be used for multi-device mounting, as described hereinafter, after fanning a solder resist layer having arbitrary openings. It is also possible to use the stage shown in FIG. 20(g) or 20(h) as the core board, an both the surfaces of which the dielectric resin layers and conductive-wiring layers are alternately formed using an additive process, a semi additive process, or a subtractive process. The circuit board having the state shown in FIG. 20(g) or 20(h) may be embedded in another circuit board after dicing the same into separate pieces.

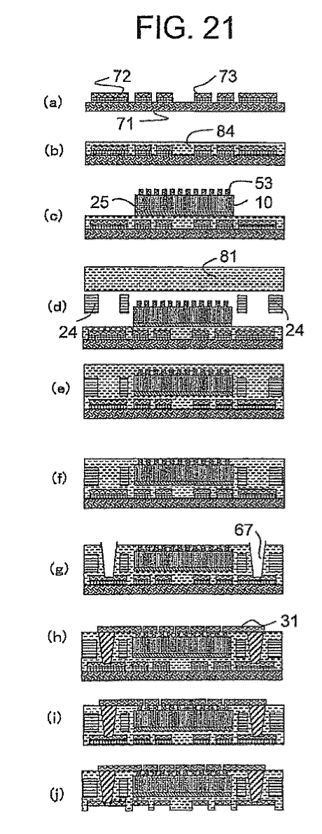

FIGS. 21(a) to 21(j) are sectional views of respective fabrication stages in a second exemplary embodiment of the circuit-board manufacturing process of the present invention. The conductive-wiring layers 72 and 73 are formed by a plating technique, an inkjet technique etc. on the supporting substrate 71 in FIG. 21(a), similarly to FIG. 20(a). Thereafter, as shown in FIG. 21(b), the dielectric resin layer 84 is supplied. Since the dielectric resin layer 84 exists directly under the functional device 10 even after removing the supporting substrate 71, the conductive-wiring layers 72 and 73 may be formed as a uniform pattern having a large area for achieving a higher heat radiation function, or in an alternative, formed to have an arbitrary wiring shape, such as BGA pads and flip-chip pads, although the shape is not limited thereto. Supply of the dielectric resin layer 84 may use a vacuum laminator, a vacuum pressing machine, a roll coater, a spin coater, a curtain coater etc., and is not limited thereto.

In a subsequent step, as shown in FIG. 21(c), the functional device 10 is bonded onto the dielectric resin layer 84 with an intervention of the adhesive layer 25. Thereafter, as shown in FIG. 21(d), the dielectric resin layer 81 and intermediate layer 24 comprised of metal or ceramics are provided using a vacuum laminator or vacuum pressing machine to encapsulate the circumference of the of the functional device 10, as shown in FIG. 21(e). At this stage, the number of species of dielectric resin layers used may be single, and it is preferable that this circuit board be designed to have a smaller degree of warp after removing the supporting substrate 71, and the arrangement of the dielectric resin layer is preferably determined in consideration of the reliability of products and workability during the manufacture thereof as well as close adhesiveness with respect to the material of functional device 10. If the dielectric resin layer 81 disposed on the side surface of the functional device 10 includes a non-fluidity material, such as a glass cloth or an aramid film, a space having a size equivalent to or larger than the outer shape of the functional device 10 is provided within the dielectric resin layer 81, thereby preventing the non-fluidity material in the dielectric resin layer 81 from damaging the functional device during the pressing.

If the board has a smaller thickness, the intermediate layer 24 comprised of a metal or ceramics has the function of preventing a warp or improving the rigidity. Since a laser processing is performed in a later step for forming vias that connect together the conductive-wiring layer 73 and the conductive-wiring layer 31, if the intermediate layer 24 itself is of a conductor or material for which the laser processing is difficult, it is needed to form openings in an arbitrary position of the intermediate layer 24, which are larger in size than the outer shape of the vias, and an opening having a size equal to or larger than the outer shape of the functional device at the location where the functional device 10 is to be forted.

In a subsequent step, as shown in FIG. 21(f), the electrode terminals 53 are exposed on the surface by using a winding device, a buff-polishing device etc. The surface height of the electrode terminals 53 exposed on the surface at this stage is the same as the height of the surrounding dielectric resin layer 81. A range of variation of the height that is 20 μm or less, if it occurs depending on the roughness of the whetstone or buffing material used for winding at this stage, is well within the scope of the present invention. As shown in FIG. 21(g), the via-holes 67 may be formed in the dielectric resin layer to reach any arbitrary conductive-wiring layer 86 in the vicinity of the supporting substrate 71, by using a laser equipment such as CO2 laser or UV-YAG laser.

After a subsequent desmear processing for washing the resin residues away from the inside of vias, the supporting substrate 71, which is of a metal, may be used to provide electric charge for directly plating the inside of vias on the side near the supporting substrate 71, if the via-holes have a height significantly larger than the inner diameter thereof. However, it is possible to use an electroless metal plating or sputtering treatment, as described with reference to FIG. 20. A metal plating is performed for the inside of via-holes 67 up to the height equal to or higher than the surface of dielectric resin layer 81, and thereafter, the surface of dielectric resin layer 81 is planarized using a buff-polishing device, a grinding device etc.

Note that it is efficient to perform grinding or buff-polishing of the electrode terminals 53 shown in FIG. 21(g) simultaneously with the buff-polishing or grinding the via-holes 67 after plating the inside thereof. If the simultaneous plating of the inside of via-holes 67 and the conductive-wiring layer 31 is to be performed, a desmear processing is performed to wash the inside of via-holes 67, as shown in FIG. 21(h), the seed layer is formed by an electroless plating or sputtering processing, and thereafter, a metal plating is performed onto the conductive-wiring layer 31 and the inside of via-holes 67. At this stage, it is also possible to form a conductive paste pattern by using an ink-jet technique or printing technique. Subsequent to formation of the conductive-wiring layer 31, the plating resist and excessive seed layer are removed.

Subsequent processings, which are similar to those in FIG. 20(g) and FIG. 20(h), remove the supporting substrate 71 in FIG. 21(i), and exposes the conductive-wiring layer 73 from the surface in FIG. 21(j). The circuit board thus obtained may be used as it is, or may be used for multi-device mounting after forming a solder resist layer having therein arbitrary openings. The solder resist layer may be formed only on one of the surfaces of the circuit board. It is also possible to use the circuit board at the stage of FIGS. 21(i) and 21(j) as the core board, and form the conductive-wiring layers and dielectric resin layers alternately each other on both the surfaces thereof, by using an additive process, semi-additive process, or subtractive process to obtain a circuit board having multilevel interconnections.

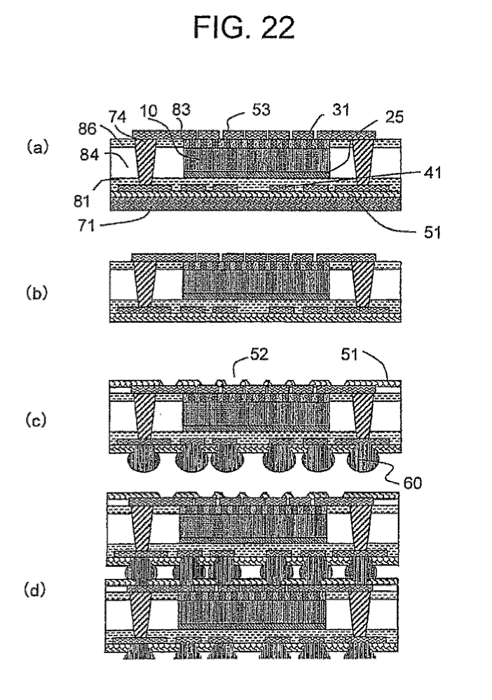

FIGS. 22(a) to 22(d) are sectional views of respective fabrication stages in a third exemplary embodiment of the circuit-board manufacturing process of the present invention. As shown in FIG. 22(a), a dielectric layer to be used as the solder resist layer 51 is supplied in advance onto the supporting substrate 71, followed by forming the conductive-wiring layer 41 thereon. Thereafter, similarly to the steps of FIGS. 21(c) to 21(i), the functional device 10 is mounted thereon, the circumference of the functional device 10 is encapsulated by the dielectric resin layers 81 and 84, and the conductive-wiring layers 31 and 41 are connected together through the via-plugs 74, whereby the functional device 10 and the circuit board of the present invention are electrically connected together through the electrode terminals 53. In subsequent steps, the supporting substrate 71 is removed, as shown in FIG. 22(b), to thereby expose the dielectric resin layer 51 from the surface, and openings 52 are formed therein using laser etc. at the location corresponding to the electrode terminals of parts to be mounted on the circuit board, whereby the dielectric resin layer functions as the solder resist layer 51. The opposite surface is also provided with the solder resist layer 51 having openings 52 therein.

Subsequently, as shown in. FIG. 22(c), solder balls 60 are mounted within the openings 52 of one of the solder resist layers 51, a plurality of such circuit boards each including the solder balls are used as packages and respectively subjected to an electric test, followed by stacking the packages and reflowing the same to obtain stacked circuit boards. Although stacking together a plurality of circuit boards each including therein a functional device causes a larger overall volume as compared to the case where a plurality of species of and a plurality of functional devices are configured to form a single circuit board, it is possible to perform the electric test for each circuit board in an intermediate step of fabrication, thereby achieving improvement of the product yield.

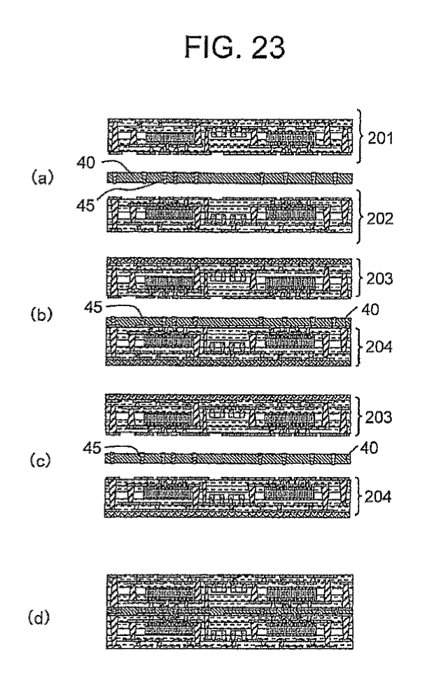

FIGS. 23(a) to 23(d) are sectional views of respective fabrication stages in a fourth exemplary embodiment of the circuit-board manufacturing process of the present invention. As shown in FIG. 23(a), two circuit boards 201 and 202, which include the functional device and from which the supporting substrate is removed of the present invention, are arranged in the vertical direction, and an adhesive layer 40 including a pattern of vias 45 filled with solder paste or conductive paste is interposed therebetween. In an alternative, as shown in FIG. 23(b), the adhesive layer 40 is supplied in advance onto the circuit board 204, via-holes are formed by laser etc., the via-holes are filled with solder paste or conductive paste, and the circuit boards 203 and 204 of the present invention which include the functional device and from which the supporting substrate is not removed are opposed to each other. In a further alternative, as shown in FIG. 23(c), the circuit boards 203 and 204 of the present invention which include the functional device and from which the supporting substrate is not removed are opposed to each other, and the adhesive layer 40 including a pattern of vias 45 filled with solder paste or conductive paste is interposed therebetween.

At this stage, a ceramic part may be embedded in advance within the circuit boards 201 and 202 that embed therein the functional device of the present invention. The embedded ceramic part is connected to the conductive-wiring layer of the circuit board of the present invention via the conductive paste or plating. Thereafter, coupling of the upper board and the lower board of the present invention at the insulator portion by using the adhesive layer 40, and electrical connection using the vias 45 are simultaneously performed by using a pressing technique etc., and if there exists the supporting substrate, the supporting substrate is removed therefrom, thereby obtaining a circuit board wherein layers including the functional device are stacked one on another in the vertical direction, as shown in FIG. 23(d).

The adhesive layer 40 may preferably include epoxy, polyimide, liquid crystal polymer etc. as the base material, and is not limited thereto. An aramid unwoven cloth, an aramid film, a glass cloth, and a silica film may be preferably used as the content material included in the adhesive layer 40 for achieving a higher strength and a higher-speed transmission, and the content material is not limited thereto. The circuit boards of the present invention used for bonding may be bonded together even in the state where the supporting substrate is removed therefrom. If at least one board includes the supporting substrate, an advantage is obtained in that a vacuum pressing can uniformly press the boards, to thereby achieve a higher reliability in the bonding that uses the adhesive layer 40 and vias 45.

The adhesive layer 40 may also be obtained by forming the via-holes by using laser, such as CO2 laser, UV-YAG laser and a drill, in the state where the protective film, such as PET and PEN, is attached in advance onto both the surfaces, and filling the via-holes with powder including elements, such as Sn, Ag, Cu, Si, Ni, Fe, Ge, Mg etc., without limitation of the elements thereto, by printing using solder paste and conductive paste through the protective film, and removing the protective film. Even without the protective film, it is possible to use a metal mask or screen mask for the printing. It is also possible to fill the via-holes with powder by using an ink jet technique.

The adhesive layer 40 may be supplied in advance onto one of the circuit boards of the present invention by using a laminating technique or pressing technique, followed by forming therein vias by using laser etc, and by printing using a protective film, a metal mask or screen mask or filling the via-holes with paste by using ink-jet technique. If the protective film is used, the protective film is removed, and a vacuum pressing is performed to bond together the two circuit boards of the present invention. This may be used as it is, or may be used after forming a solder resist layer having therein arbitrary openings for multi-device mounting.

It is possible to use the state of FIG. 23(d) as the core board for alternately forming conductive-wiring layers and dielectric resin layers on both surfaces thereof by using an additive process, a semi-additive process or a subtractive process. Two functional-device-embedded circuit boards of the present invention, from which the supporting substrate is removed or not yet removed or which includes only a single supporting substrate on one of the surfaces, and which includes the adhesive layer and layers connected through the vias, are prepared, and coupled together with an intervention of a new adhesive layer 40 and vias filled with solder paste or conductive paste, by using a vacuum pressing technique, to achieve a circuit board including a further increased number of stacked layers. In this case, as a matter of course, the supporting substrate should be removed in advance from the surface of the functional-device-embedded circuit board, which is to contact the new adhesive layer 40. In this way, a circuit board can be achieved which includes multi-level interconnections, is superior in the high-speed electric characteristic and has a smaller size.

FIG. 26 is a sectional view of a fabrication stage of a fifth exemplary embodiment of the circuit-board manufacturing process of the present invention. At least one conductive-wiring layer and at least one dielectric layer are provided on one or both of the surfaces of the circuit boards 410 used as a core layer, while using the circuit boards 410 embedding therein the functional device 10 of the present invention, followed by embedding a plurality of these circuit boards 410 in a larger-sized circuit board 411. At this stage, the conductive-wiring layer, for which the terminal pitch is increased by connecting the same to the electrode terminals 53 of the functional device 10, is designed to be located on the surface of the circuit boards 410, whereby the circuit boards 410 can be subjected to an electric test with case before embedding the same in the larger-sized board 411.

By embedding in the larger-sized board 411 only the circuit boards 410 that are judged as non-defective devices in the electric test, the product yield can be increased to thereby reduce the fabrication cost. Further, since the conductive-wiring layer in the circuit boards 410 is connected directly to the electrode terminals 53 of the embedded functional device 10, if the conductive wiring dose not include relatively fine interconnections and thus can be formed using the subtractive technique that provides a lower cost, the step of forming the conductive wiring can be performed at separate two sites thereof to achieve an efficient mass production that achieves a superior product yield and a lower cost, although the semi-additive technique that provides fine conductive wiring is typically employed.

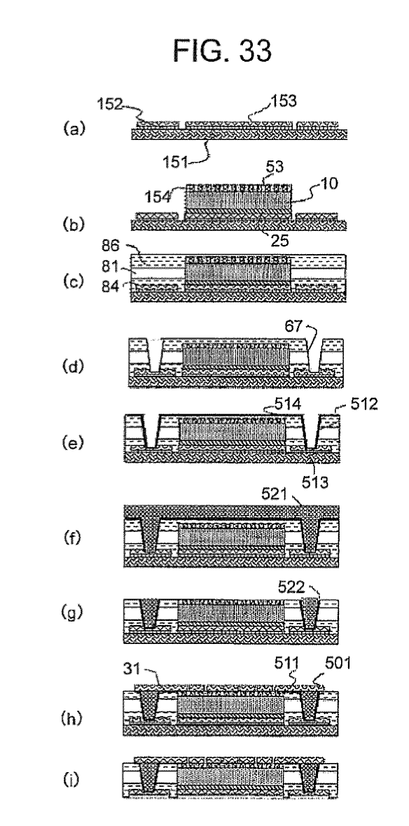

FIG. 33 are sectional views of respective fabrication stages in a sixth exemplary embodiment of the circuit-board manufacturing process of the present invention. First, as shown in FIG. 33(a), a substrate is formed by forming conductive-wiring layers 152 and 153 on a supporting plate 151 in this order. Next, as shown in FIG. 33(b), a functional device 10 is mounted on the board with an intervention of the adhesive layer 25, with the electrode terminals 53 being upward, after providing the protective layer 154, if necessary, on the surface of the functional device. In a subsequent process, as shown in FIG. 33(c), the dielectric resin layers 81, 84 and 85 are supplied to embed therein the functional device 10, and as shown in FIG. 33(d), the vias of the conductive-wiring layer 153 are formed from the opposite surface of the supporting plate 151 by using laser.

Thereafter, in the step of FIG. 33(e), a seed layer is formed on the entire surface by using an electroless plating or sputtering technique. In a subsequent step, as shown in FIG. 33(f), plating, an AD (aerosol deposition) technique or conductive-paste printing is performed on the entire surface so that the conductor layer 521, such as Au, Ag, Cu and Ni, is formed to fill the via-holes 67. The after, in the step of FIG. 33(g), grinding or etching is performed to form vias 501 so that the embedded electrode terminals 53 and the exposed surface of the vias 522 are located on the same plane. Subsequently, as shown in FIG. 33(h), after forming the seed layer 511, the plating resist pattern is formed and the conductive-wiring layer 31 is formed by plating etc. In a subsequent step, as shown in FIG. 33(i), the supporting plate 151 and conductive-wiring layer 152 are removed by etching, grinding etc., to thereby obtain the circuit board 115 shown in FIG. 29.

Here, in the step shown in FIG. 33(g), the vias 522 and electrode terminals 53 can be observed at the same time, whereby the positional accuracy during patterning the conductive wiring by using exposure is superior to hereby improve the product yield. Since the seed layer exists on the entire interface of the top portion, bottom portion and side surface of the vias, the vias 501 maintain a higher strength against the stress applied three-dimensionally to thereby improve the reliability.

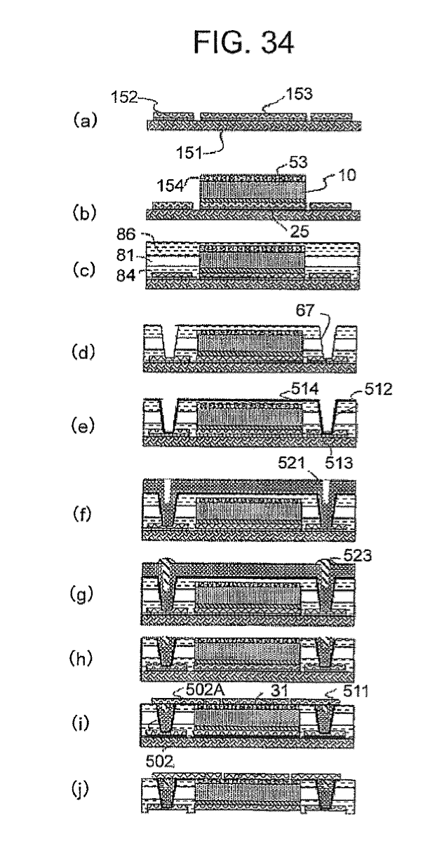

FIG. 34 are sectional views of respective fabrication stages in a seventh embodiment of the circuit-board manufacturing process of the present invention. First, as shown in FIG. 34(a), a substrate is formed by depositing the conductive-wiring layers 152 and 153 in this order on a supporting plate 151. Next, as shown in FIG. 34(b), the functional device 10 is mounted thereon with an intervention of the adhesive layer 25, with the electrode terminals being upward, after supplying the protective layer 154, if necessary, onto the circumference of the electrode terminals 53 of the functional device. In a subsequent step, as shown in FIG. 34(c), dielectric resin layers 81, 84 and 85 are supplied to embed therein the functional device 10, and as shown in FIG. 34(d), vias to reach the conductive-wiring layer 153 are formed from the opposite surface of the supporting plate 151 by using laser.

Thereafter, in the step of FIG. 34(c), a seed layer is formed on the entire surface by an electroless plating or sputtering technique. In a subsequent step, as shown in FIG. 34(f), plating, an AD process or conductive-paste printing is performed on the entire surface so that a conductor layer 521, such as Au, Ag, Cu and Ni, is formed to fill the via-holes 67. At this stage, if the conductor layer 521 has a smaller thickness, the via portion is insufficiently filled to form therein a void on the upper central portion thereof, unlike the fabrication process of FIG. 33. Thus, in a subsequent step, as shown in FIG. 34(g), resin 523 is supplied in the void portion. Thereafter, in the step of FIG. 34(h), grinding or polishing is performed so that the embedded electrode terminals 53 and the exposed surface of vias are located on the same plane. Subsequently, in the step of FIG. 34(i), after forming a seed layer 511, a plating resist pattern is formed, and the conductive-wiring layer 31 is formed by plating etc. In a subsequent step, as shown in FIG. 34(j), the supporting plate 151 and conductive-wiring layer 152 are removed by etching, grinding etc., to thereby obtain the circuit board 116 shown in FIG. 30.

Here, in the step shown in FIG. 34(i), since the vias 502 and electrode terminals 53 can be observed at the same time, the positional accuracy during patterning the conductive wiring by using exposure is superior to improve the product yield. Since the seed layer exists on the entire interface of the top portion, bottom portion and side surface of the vias, the vias 502 have a higher strength against the stress applied thereto three-dimensionally, to thereby improve the reliability. In addition, since the conductor layer provided to the entire surface in the step shown in FIG. 34(f) in the fabrication process of the present exemplary embodiment has a smaller thickness as compared to the fabrication process shown in FIG. 33, the time length needed for grinding or polishing the electrode terminals and vias in the step of FIG. 34(h) can be reduced.

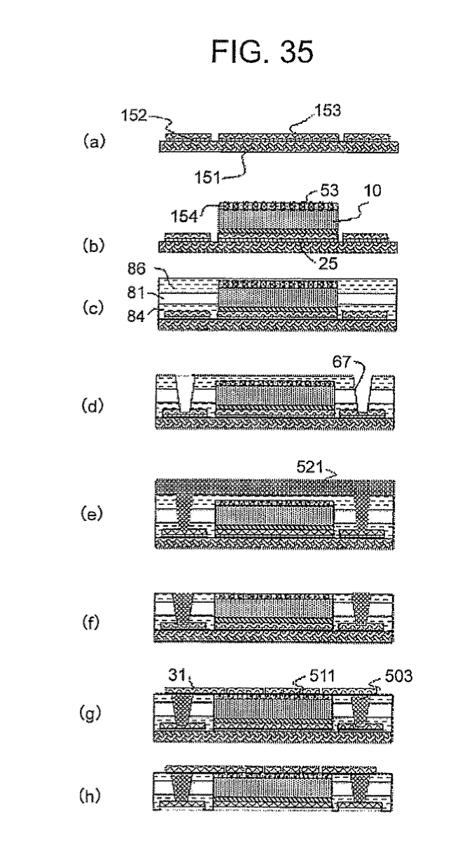

FIG. 35 are sectional views of respective fabrication stages in an eighth exemplary embodiment of the circuit-board manufacturing process of the present invention. First, similarly to FIG. 33, steps shown in FIGS. 35(a) to 35(d) are performed. After these steps, as shown in FIG. 35(e), an AD process is performed to fill the via-holes 67 that penetrate the conductor layer 521 with metal powder without forming the seed layer. In a subsequent step, etching or polishing is performed so that the electrode terminals 53 are exposed, as shown in FIG. 35(f). Thereafter, as shown in FIG. 35(g), the conductive-wiring layer 31 is formed after forming the seed layer 511. In a subsequent step, as shown in FIG. 35(h), the supporting plate 151 and conductive-wiring layer 152 are removed by etching, grinding etc., to obtain the circuit board 117 shown in FIG. 31.

It is possible for the AD process to form a thicker film in a short period of time as compared to the plating. Thus, use of the AD process considerably reduces the fabrication time length, and forms a finer metal structure having smaller crystal grains within a portion of the vias 503 having a smaller inner diameter and located near the conductive-wiring layer 153, and on the other hand, forms a larger crystal-grain diameter within a portion of the vias 503 having a larger inner diameter and located near the conductive-wiring layer 31, as compared to that near the conductive-wiring layer 153, thereby improving the reliability of products. In addition, a concentrated energy is applied to the bottom portion of vias 503, whereby a superior bonding strength is obtained at the bottom portion of vias to achieve a higher reliability.

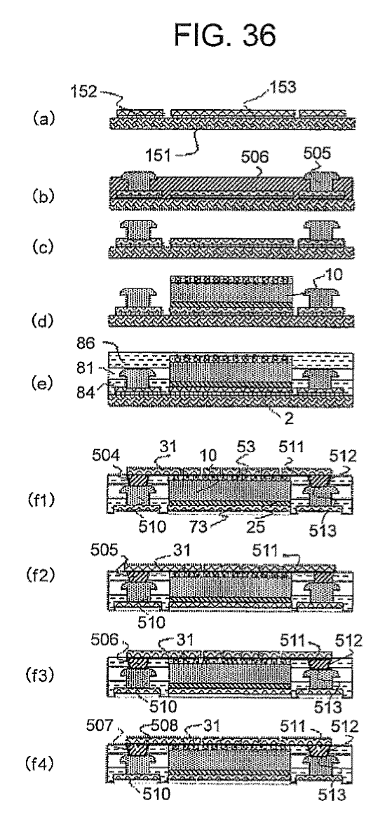

FIG. 36 are sectional views of respective fabrication stages in a ninth exemplary embodiment of the circuit-board manufacturing process of the present invention. First, in the step of FIG. 36(a), the conductive-wiring layers 152 and 153 are formed on a supporting plate 151. Then, as shown in FIG. 36(b), plating resist is supplied thereto and a post pattern is formed on the wiring 153 by using exposure and development. Thereafter, plating is performed so that the plating thickness is equal to or larger than the resist thickness, to form mushroom-shaped posts 510. At this stage, if the supporting plate 15.1 is of a metal, electric power may be fed through the supporting plate 151. In a subsequent step, as shown in FIG. 36(e), the resist is removed and the functional device is mounted thereon as shown in FIG. 36(d). In a subsequent step, as shown in FIG. 36(c), the functional device 10 is embedded within the dielectric resin layers 81, 84 and 85. At this stage, the mushroom-shaped posts 510 are embedded simultaneously. Thereafter, vias are formed using laser.

In the step shown in FIG. 36(f1), the seed layers 511, 512 and 513 are formed as a common seed layer, and the conductive-wiring layer (plating conductive-wiring layer) 3 using a plating resist is formed, to thereby obtain the circuit board 118A including via-plugs 504 formed therein and shown in FIG. 32. In the step of FIG. 36(f2), electric power is supplied from the supporting plate 151, to perform conductor plating or conductive-paste printing of the vias-plugs 505 and thereby form the conductive-wiring layer 31 having the seed layer 511 only on the top portion of vias-plugs 505, to obtain the circuit board 118B shown in FIG. 32. In the step of FIG. 36(f3), after forming openings by using laser, steps similar to those of FIG. 33(e) to FIG. 33(i) are performed to form via-plugs 506 including the seed layers 513, 511 and 512 on the bottom portion, top portion and side surface thereof, to obtain the circuit board 118C shown in FIG. 32. Further, in the step shown in FIG. 36(f4), a process similar to that shown in FIGS. 34(c) to 34(j) is performed, to fill the top portion of the center of vias with the resin 508, thereby obtaining the circuit board 118D shown in FIG. 32.

Irrespective of any techniques used, since the mushroom-shaped posts 510 are formed in advance to be embedded within the resin, in a subsequent laser processing for forming the via-holes, the post portion embedded within the resin is observed above the conductive-wiring layer 73. Thus, recognition of position with a higher accuracy can be obtained, to thereby improve the product yield. Due to presence of the pileus structure portion in the mushroom-shaped posts 510, a superior strength and improved reliability can be obtained as described before. In addition, since the vias formed by laser have a smaller height, the aspect ratio of vias is reduced, whereby removal of residues on the bottom portion of the vias generated during patterning the resist is facilitated and at the same time, the plating liquid in the plating bath well flows onto the bottom portion of vias to thereby achieve a reliable portion of vias near the conductive-wiring layer 31.

### EXAMPLES

Hereinafter, the present invention will be described more concretely with reference to examples.

### (Circuit Board)

A first example according to the first embodiment of the present invention will be described with reference to FIGS. 1 to 3. In FIG. 1, the base material of the functional device 10 was GaAs and silicon. The electrode terminals 53 were formed to have a height of 5 μm to 50 μm by using a copper plating. A die-attachment film was used as the adhesive layer 25. It was confirmed that any of “LE-4000” (trademark) and “LE-5000” (trademark) from LINTEC Corp. and “DF402” (trademark) from Hitachi Chemical Co., Ltd. can be used for the die-attachment film.

Epoxy-based materials that contained glass cloth, that contained an aramid unwoven cloth and that used an aramid film were used as the dielectric resin layer 81. It was also confirmed that polyimide can be used as well. More specifically, prepregs now on the marketed, such as “ABF-GX” from Ajinomoto Co., Inc., and “GEA-679FG” from Hitachi Chemical Co., Ltd. etc., were used. In addition, “PIMEL” from Hitachi Chemical Co., Ltd. that is in liquid form before curing, and “BCB” from DOW Corp. could be used as well for forming the same. The surface of conductive-wiring layer 41 was formed at 0 to 20 μm lower than the surface of dielectric resin layer 81. The function of the dielectric resin layer 81 for protecting the functional device 10 was superior in the case that functional device 10 had a thickness of 200 μm or less.

In FIG. 2, at least one species of element selected from Ti, W, Cr, Pt, Au, Cu, Ni, Ag, Sn and Pd is preferably used for the seed layer 55, which is not limited thereto however. The seed layer 55 may be provided using electroless plating, sputtering technique, printing technique etc. More specifically, a 30- to 200-nm-thick Ti and a 200- to 400-nm-thick Cu were consecutively formed using a sputtering system between the dielectric resin layer 81 and the bottom of the conductive-wiring layer 31. The seed layer 55 could also be formed using a consecutive sputtering processing of a combination of Cr layer and Cu layer, or combination of Pd layer and Cu layer. The seed layer 55 can also be formed using an electroless Cu plating, and in this case, some quantity of Pd and Sn may be included therein for a substituted plating.

As a pretreatment for forming the seed layer 55, a desmear processing that typically uses KMnO4, NaMnO4 etc. is performed to roughen the surface of dielectric resin layer 81 and exposed surface of the electrode terminals 53, whereby the surface has a roughness of around 10 μm or less. This roughening processing increases the adhesive strength between the dielectric resin layer 81 and the seed layer 55 and conductive-wiring layer 31, thereby improving the reliability of products.

As the conductive-wiring layer 31, Cu was deposited to a thickness of 5 to 25 μm. If an inactive metal was needed, Au was used. When Cu was used for forming the wiring, electroless plating using Ni and Au was performed onto the surface to prevent oxidation of the surface, although this may be used as it is. Sn, Sn—Ag or Sn—Ag—Cu solder was provided onto the surface of the electrode wiring 3 depending on the surface mounting process by using paste printing and reflow processing. After forming the conductive-wiring layer 31, an excessive amount of seed layers 55 other than the circuit pattern is etched by a chemical etching or IBE (ion beam etching), for using the conductive-wiring layer as a circuit.

In FIG. 3, if the dielectric resin layer 82 is to be used, it is preferable that the dielectric resin layer 82 be superior in the workability during CO2 or UV-YAG laser processing or be a photosensitive resin, in order to maintain the openings formed by grinding for exposing therethrough a portion of the electrode terminals 53. The diameter of openings of the dielectric resin layer 82 was made smaller than the diameter of electrode terminals 53, whereby it is possible to increase the number of interconnections extending between adjacent terminals of the ordinary electrode terminals 53 to thereby reduce the overall volume of the board.

With reference to FIG. 4, a second example according to the second exemplary embodiment of the present invention will be described. The thickness of each of the dielectric resin layers 81, 84 and 85 was 10 to 500 μm. The thickness of the dielectric resin layers 81, 84 and 85 can be changed depending on the thickness of the functional device 10 to be embedded. As the dielectric resin layers 84 and 11 in the vicinity of the front surface and rear surface of the circuit board, a soft resin, such as polyimide-based resin and epoxy-based resin, having a higher strength against an external bending stress and cracks is used, whereas as the dielectric resin layer 81 in the vicinity of the functional device 10, an manic resin such as including glass cloth, glass fillers, an aramid unwoven cloth, and an aramid film is used, whereby the thermal coefficient of expansion is close to that of the functional device 10, to thereby suppress occurring of cracks between the resin and the functional device and to thereby improve the reliability.

With reference to FIGS. 5 to 10, a third example according to the third embodiment of the present invention will be described. Ag paste obtained by mixing Ag powder and epoxy-based resin for kneading was used for the adhesive layer 25. A liquid resin including epoxy, polyimide, benzocyclobutene etc. as the base material could be used as well for the adhesive layer 25. In this case, a specific quantity of resin configuring the adhesive layer 25 was selectively provided onto a position of the conductive-wiring layer mounting thereon the chip by potting using a dispenser or by a printing technique.

The thickness of the conductive-wiring layers 31 and 41 was 1 to 20 μm. Upon forming via-holes 61, a laser processing was performed from above. This processing formed a shape of via-holes 61 having a smaller diameter toward the bottom surface thereof and a uniform taper angle. The bottom of via-holes 61 may have sometimes a shape such that a part of the resin configuring the vias has an inner diameter increased by 10 μm due to the heating by laser. The via-plugs 74 were formed by a plating technique using conductive paste including copper and Sn—Ag based powder.

With reference to FIG. 11, a fourth example according to the fourth embodiment of the present invention will be described. Resistors 21 were formed from titanium nitride or titanium oxide, and dielectric bodies 22 were formed from tantalum oxide or strontium titanium oxide. Inductors 23, which are generally difficult to form on an LSI due to a smaller Q-value, can be formed with ease on the circuit board, to thereby achieve a higher function with a smaller volume.

With reference to FIG. 12, a fifth example according to the fifth embodiment of the present invention will be described. A 0.05- to 0.3-mm-thick stainless steel, SUS304, and a kovar alloy group were used for the intermediate layer 24. The intermediate layer 24, which was connected to the conductive-wiring layers 31 and 41 through Cu-plated vias, was used as a ground layer to achieve superior electric properties. The intermediate layer 24 was also foamed from a ceramic substrate including SiO2 and Al2O3. In this case, a plurality of conductive-wiring layers were formed within the ceramic substrate, to thereby achieve formation of a circuit board having a further increased number of layers. In addition, by using the circuit board 107 as a core board, a subtractive process was performed to form a plurality of conductive-wiring layers and a plurality of dielectric resin layers on both surfaces of the circuit board at a lower cost. In this case, a lower-cost, higher-performance multi-layer circuit board can be provided.

With reference to FIG. 13, a sixth example according to the sixth embodiment of the present invention will be described. “PIMEL” from Hitachi Chemical Co., Ltd., and “BCB” from DOW Co. etc. were used for the dielectric resin layer 83. With reference to FIG. 14, a seventh example according to the seventh embodiment of the present invention will be described. The conductive-wiring layers 32 and 33 were formed from copper and was 2 to 20 μm thick. The thickness of dielectric resin layers 81, 84 and 85 was 5 to 80 μm.

With reference to FIGS. 16 to 18, an eighth example according to the eighth embodiment of the present invention will be described. In FIGS. 16 to 18, epoxy resin generally referred to as a prepreg material and including a glass cloth or epoxy resin including an aramid unwoven cloth was used for the adhesive layer 40, with the thickness of the epoxy resin being 20 to 80 μm. The conductive paste used herein included powder configured by elements of Sn, Ag, Bi, Cu etc., and had a composition determined depending on the temperature of the fabrication process. The grain diameter of the powder was 10 μm or less for the case where the inner diameter of vias 45 was 100 μm or less. In FIG. 18, the thickness of solder resist layer 51 was 5 to 20 μm.

With reference to FIG. 19, a ninth example according to the ninth embodiment of the present invention will be described. FIG. 19 shows the structure wherein the conductive-wiring layer 31 is electrically connected to the electrode terminals 53 of the functional device 10A embedded within the dielectric resin layer 81, and wherein the conductive-wiring layer 34 connects together the top portion of the functional device 10 and the peripheral area thereof in an area where neither the electrode terminals 53 of the embedded functional device 10A nor the electrode terminals 54 connected to a conductive-wiring layer formed next to the conductive-wiring layer 31 exists, and where the conductive-wiring layer 31 does not exist.

The conductive-wiring layer 34 has the function of preventing the embedded functional device 10A from being damaged by a bending or stroking stress. Here, the conductive-wiring layer 34 can be electrically used as the ground, has the function of an electromagnetic shield, and can provide superior electric properties for the products. In particular, high-frequency electric properties at 1 GHz or above can be improved as compared to the case of absence of the conductive-wiring layer 34. The conductive-wiring layer 34, if connected to the electrode terminals 53 used as the ground of functional device 10A, can further improve the electric properties as well.

With reference to FIG. 29, a tenth example according to the tenth embodiment of the present invention will be described. In FIG. 29, the functional device 10 comprised of silicon is fixed onto the conductive-wiring layer 73 with an intervention of the adhesive layer 25, and embedded within a plurality of epoxy-based dielectric resin layers. Conductor vias 501 having a diameter of 100 μm to 50 μm that connect together the conductive-wiring layer 31 and the conductive-wiring layer 73 are formed on the side surface of the functional device 10. The seed layers 512, 513 and 511 are formed on the side surface, bottom surface and top surface, respectively, of vias 501, thereby improving the adhesive strength with respect to the dielectric resin and the adhesive strength with respect to the conductive-wiring layer 31. Here, the vias 501 are filled vias that are filled with copper by plating. The seed layer 511 is formed from titanium and copper; and is formed also between the electrode terminals 53 of the functional device 10 and the conductive-wiring layer 31 that are embedded at the same time.

As described above, provision of the seed layer onto the side surface, bottom portion and top portion of the vias 501 prevents internal fracture of vias, fracture of the top portion and bottom portion of vias and peel-off from the resin layer at the side surface of the vias in the event of deformation of the board, which may be caused by incorporation of the functional device in the board, to thereby provide products having a higher reliability. In particular, when a heat cycle from −55° to 125° is repeated, the board exhibits a longer lifetime as high as 2000 cycles or above, although in this case the board experiences warp of opposite directions for the higher temperature and the lower temperature. In addition, formation of the electrode terminals 53 and seed layer 511 as a common layer facilitates position observation during exposure of resist in the formation of wiring pattern of the vias 501 and electrode terminals 53, thereby providing a superior positioning accuracy. Thus, the product yield can be improved. Further, use of the filled vias increases the via area in contact with the conductive-wiring layer 31 as compared to the case of using the conformal-type ones, thereby reducing the electric resistance and improving the higher-speed electric property.

With reference to FIG. 30, an example according to a first modified example of the tenth embodiment of the present invention will be described. In FIG. 30, conformal-type vias 502 wherein the conductor layer is formed only on the side surface and bottom portion of the vias by a plating technique etc. were used, as contrasted to the vias 501 shown in FIG. 29 being of a filled type. Epoxy-based resin 502A is embedded in the vicinity of the center of vias 502 near the conductive-wiring layer 31. The seed layers 512, 513 and 511 are formed on the side surface, bottom portion and top portion of vias 502 that include the resin 502A, thereby improving the adhesive strength with respect to the dielectric resin and the adhesive strength with respect to the conductive-wiring layer 31.

Thus, internal fracture of the vias, fracture oldie top portion and bottom portion of the vias and peel-off of the side surface of vias from the resin layer can be prevented in the event of deformation of the board, which may be caused by incorporation of the functional device 10 in the board, similarly to the example shown in FIG. 29, whereby products having a higher reliability can be achieved. In addition, formation of the electrode terminals 53 and the seed layer 511 as a common layer facilitated position observation during exposure of resist for forming the wiring pattern of the vias 502 and electrode terminals 53, thereby achieving a superior positing accuracy. Accordingly, the product yield could be improved. Embedding the resin 502A within the vias 502 allows the thermal coefficient of expansion of vias to be closer to that of the dielectric resin layer existing outside of vias 502, to thereby improve the reliability.

With reference to FIG. 31, an eleventh example according to the eleventh embodiment of the present invention will be described. In FIG. 31, the functional device 10 is fixed onto the conductive-wiring layer 73 with an intervention of a 25-μm-thick epoxy-based adhesive layer 25 and embedded within a plurality of dielectric resin layers. Vias 503 comprised of copper that connect together the conductive-wiring layer 31 and the conductive-wiring layer 73 are formed near the side surface of the functional device 10. Although the seed layer is not formed on the side surface and bottom portion of the vias 503, the seed layer 511 is formed on the top portion thereof to improve the adhesive strength with respect to the conductive-wiring layer 31. Here, the vias 503 is filled vias comprised of a conductor, wherein crystal grains of the conductor structure are dense at the bottom portion thereof near the conductive-wiring layer 73, and the crystal-grain diameter on the top portion thereof near the conductive-wiring layer 31 is larger as compared to the bottom portion thereof.

As a result, a portion of the internal conductor of vias 503 having a larger inner diameter and disposed near the conductive-wiring layer 31 has a larger crystal-grain diameter and a significant extending property, whereby it is possible to alleviate the stress in the event of deformation of the board, such as warp, that may be caused by incorporation of the functional device 10. On the other hand, a portion of the internal conductor of vias 503 having a smaller inner diameter and thus a smaller contact area and disposed near the conductive-wiring layer 73 scarcely extends, and yet has a superior bonding strength with respect to the conductive-wiring layer 73. Therefore, even without forming the seed layer at the interface between the side surface of vias and the conductive-wiring layer 73, disconnection of the vias can be prevented by alleviating the stress applied to the interface, thereby improving the reliability of products.

With reference to FIGS. 32(a), 32(b), 32(c) and 32(d), a twelfth example according to the twelfth embodiment of the present invention will be described. The circuit boards shown in FIG. 32 include mushroom-shaped posts 510 having a height of about 40 μm and formed on a portion of the via-plugs 504, 505, 506 and 507, which connect together the conductive-wiring layer 31 and the conductive-wiring layer 73, near the conductive-wiring layer 73 in the height-wise direction. The pileus structure portion of the mushroom-shaped posts 510 provides an outward wedge of about 20-μm length toward the dielectric resin layer in the horizontal direction of the board. There are other vias that are formed using CO2 laser on a portion of the mushroom-shaped posts 510 near the conductive-wiring layer 31.

In FIG. 32(a), via-plugs 504 are formed, seed layers 513, 512 are formed on the bottom portion and side surface thereof, and a common seed layer 511 is formed from the side surface of top portion of the via-plugs 504 through the bottom of the conductive-wiring layer 31 to the gap between the electrode terminals 53 and the conductive-wiring layer 31. The seed layers 511, 512 and 513 are formed as a continuous layer. Here, the via-plugs 504 are of the conformal type. In FIG. 32(b), via-plugs 505 are formed, and the seed layer 511, which is common for the via-plugs and electrode terminals 53, is formed only on the top portion of via-plugs between the via-plugs and the conductive-wiring layer 31. In FIG. 32(c), via-plugs 506 are formed, and seed layers 513, 512 and 511 are formed on the bottom portion (top portion of the mushroom-shaped posts 510), side surface and top portion thereof, thereby improving the reliability of strength obtained by incorporation of the functional device 10. In FIG. 32(d), via-plugs 507 obtained by filling the via-plugs 504, which are of the conformal type, with resin 508 are formed, the seed layers 513, 512 are formed on the bottom portion and side surface of the via-plugs, and the seed layer 511 is also formed above.

In this way, the pileus structure portion of the mushroom-shaped posts 510 extends as a wedge within the dielectric resin layer in a horizontal direction (direction normal to the thickness direction) of the dielectric resin layer, thereby increasing the strength in the thickness direction between the vias and the dielectric resin in the event of thickness-wise deformation or warping stress generated in the functional-device-embedded board, even without forming the seed layer on the side surface of the vias, thereby preventing disconnection at the vias. Thus, reliability of products can be improved. On the other hand, if the vias have an ordinary trapezoid section, and if there is no increased adhesion strength between the side surface of vias and the dielectric resin layer, unlike the present exemplary embodiment, there is a possibility that a peel-off of the via conductor from the dielectric resin layer in contact therewith occurs. Note that the structure of FIGS. 32(a), 32(b), 32(c) and 32(d) may be suitably selected depending on a combination of the cost of materials and the material of via-plugs 504 to 507. Use of the mushroom-shaped posts 510 increases the reliability as compared to the case without the same.

### (Process for Manufacturing Circuit Board)

With reference to FIGS. 20(a) to 20(h), a first example according to a first exemplary embodiment of the method of the present invention will be described. First, as shown in FIG. 20(a), a plating resist including a dry film and varnish is supplied onto a supporting substrate 71 comprised of copper, and the pattern of conductive-wiring layer 72 comprised of Ni is plated to a thickness of 0.5 to 20 μm by using a plating technique after the exposure and development thereof. At this stage, it is preferable that the conductive-wiring layer 72 be not solved by an etching solution, if the supporting substrate 71 is comprised of a metal, such as Cu and stainless steel, and is to be removed by etching. Thus, it is preferable that the material of conductive-wiring layer 72 be different from that of the supporting substrate 71. Au or solder plating may also be used therefor, because it is an exposed metal after the removal of supporting substrate 71. The pattern of conductive-wiring layer 72 may be comprised of a plurality of species of plating layers, instead of a single plating layer. If the removal of supporting substrate 71 uses mechanical polishing of the supporting substrate 71 or peel-off of the supporting substrate 71 by a stress, the pattern of conductive-wiring layer 72 need not be provided.

The supporting substrate 71 may be preferably comprised of a single material such as Si, glass, aluminum, stainless steel, polyimide, epoxy etc., or a composite material thereof, without limitation thereto. If the supporting substrate 71 is comprised of a nonconductive material, the conductive-wiring layer 72 may be formed thereon by providing a plating seed metal thereto by sputtering or electroless plating. If the supporting substrate 71 is to be removed by a process other than the etching, a technique for providing a releasing material in advance within the material of the supporting substrate 71 may be preferably used, without limitation thereto. For example, as a releasing layer adhered onto the board comprised of a single material such as Si, glass, aluminum, stainless steel, polyimide and epoxy, ultra-thin copper-foil series, “Micro Thin (MT)” from Mitsui Mining and Smelting Co., Ltd. may be preferably used, whereas as the supporting substrate 71, “PTFE tape” from Sumitomo 3M, Inc. may be preferably used. However, the supporting substrate 71 comprised of a composite material is not limited thereto.

The pattern of conductive-wiring layer 73 comprised of copper is then formed to a thickness of 5 to 20 μm by a plating technique, without peeling-off the plating resist or after peeling-off the plating resist and forming a pattern of another plating resist. At this stage, the pattern of conductive-wiring layer 73 preferably exists on the pattern of conductive-wiring layer 72. Since the pattern of conductive-wiring layer 73 remains after the removal of supporting substrate 71, gold, copper, nickel etc. May be used therefor.

In a subsequent step, a 10- to 725-μm-thick functional device 10 is mounted, while applying heat and pressure, on the pattern of conductive-wiring layer 73 with an intervention of a 10- to 30-μm-thick adhesive layer 25 comprised of an organic resin, as shown in FIG. 20(b). It is preferable, without limitation, that the pattern of conductive-wiring layer 73 be formed so that a planar metal is formed in the area where the functional device 10 is to be mounted, because the resultant area functions as a heat sink after the removal of supporting substrate 71. The electrode terminals 53 having a cylindrical shape or comprised of multilevel interconnections are provided in advance on the functional device 10, or Au stud bumps may be used stead thereof. The electrode terminals 53 is not limited to those configurations however. The material of electrode terminals 53 may be Cu, Ag, Ni etc., without limitation thereto. For the case where protection of the chip active area is desired, a dielectric resin layer 83 is provided. The electrode terminals 53 of the functional device 10 may be embedded within the dielectric resin layer 83 before the mounting, without exposure thereof on the surface.

In a subsequent step, as shown in FIG. 20(c), several dielectric resin layers am provided from above the electrode terminals 53 of the functional device 10 and cured, by using a vacuum pressing at a peak temperature of 160 to 300° so long as the dielectric resin layer include an epoxy resin. For the case where the dielectric resin layer included polyimide, the resin curing was performed at a peak temperature of 200 to 400° after supplying the polyimide resin by using a spin-coat technique etc. At this stage, a suitable combination of dielectric resin layers and a suitable deposition order of the dielectric resin layers should be employed in order not to incur warp of the circuit board after the removal of supporting substrate 71. If the dielectric resin layer 81 located on the side surface of the functional device 10 includes a non-fluidity material, such as a glass cloth or an aramid film, a space having a size equal to the outer shape of the functional device 10 or having a margin of around 0.1 to 1 mm added thereto in one direction may be provided within the dielectric resin layer 81, whereby the non-fluidity substance included in the dielectric resin layer docs not damage the functional device 10 during the pressing. The number and species of the dielectric resin layers may be judged as desired depending on the thickness of the embedded functional device 10 and the overall thickness of the board, and a single layer may be used.

In a subsequent step, as shown in FIG. 20(d), the etc trade terminals 53 are exposed on the surface by using a grinding device, a buff-polishing device etc. The surface height of the electrode terminals 53 exposed on the surface at this stage is the same as that of the surrounding dielectric resin layer 86. The roughness of the whetstone or buffing material used for the winding at this stage may cause a range of variety of height as wide as 20 μm or smaller, which is well within the scope of the present invention. Thereafter, as shown in FIG. 20(c), 20- to 800-μm-diameter via-holes 67 were formed in the dielectric resin layer 86 to reach an arbitrary conductive-wiring layer 73 in the vicinity of the supporting substrate 71 by using a UV-YAG laser equipment. At this stage in this example, since the alignment mark is polished together with the electrode terminals 53 in the step of FIG. 20(d), the mark itself is exposed on the surface, whereby a superior positioning accuracy can be achieved during the laser processing, thereby improving the yield during manufacture of products. Note that if the vias are not formed, the subsequent step of electroless plating, electrolysis plating etc. do not connect together the conductive-wiring layers 31 and 73 on the top and bottom of the functional device. However, the conductive-wiring layer 73 provides the advantage of heat radiation and protection of the functional device, and the conductive-wiring layer 31 increases the wiring rule of the electrode terminals 53, which may also be used as external terminals.

After forming the via-holes 67 in the dielectric resin layer 86, a desmear processing is performed to remove the resin residues within the via-holes 67, and at this stage, the resin residues etc. comprised of polished particles and existing on the exposed portion of the electrode terminals 53 can also be removed at the same time. The surface of dielectric resin layer 86 has thereon concave-convex portions of 10-μm height or smaller caused by the desmear processing, providing the advantage of increasing the adhesive strength after forming the conductive-wiring layer 31 due to an anchor effect. After cleaning the conductor wiring by using a weak acid, such as dilute sulfuric acid, an electroless plating using copper, nickel etc., is performed to obtain a seed layer for the subsequent plating process. Instead, a sputtering processing may be performed to form at least one conductor layer including at least one species of element, comprised of a combination of Ti layer and Cu layer, combination of Pd layer and Cu layer, or combination of Cr layer and Cu layer. The elements configuring the seed layer were selected for achieving an efficient proceeding of the process for forming resistors, inductors, and capacitors, which are shown in FIG. 11.

In a subsequent step, as shown in FIG. 20(f), a plating resist layer was formed, the conductive-wiring layer 31 was formed, and copper plating was performed onto the inside of via-holes 67, the plating resist was removed thereafter, and the plating seed layer other than for the wiring pattern was etched. In a subsequent step, as shown in FIG. 20(g), when the supporting substrate 71 was copper, etching was performed using a copper-etching solution, to expose the conductive-wiring layer 72 comprised of Ni. At this stage, the height of conductive-wiring layer 72 is the same as that of the dielectric resin layer 84 surrounding the periphery thereof. This may be used as the circuit board in this state; however, the conductive-wiring layer 72 comprised of Ni may be etched in a subsequent step by using a nickel remover that is different from the chemical liquid used for etching the supporting substrate 71 etc., to expose on the surface the conductive-wiring layer 73 comprised of copper, as shown in FIG. 20(h).

The height of conductive-wiring layer 73 comprised of copper at this stage is about 0.5 to 20 μm lower than that of the dielectric resin layer 84 surrounding the periphery thereof. The height of conductive-wiring layers 72 and 73, which are originally formed on the supporting substrate 71, is uniform and thus can be suitably used as the electrode terminals by which the surface mounting is performed in the semiconductor device or BGA package, achieving a higher connection reliability. The circuit board thus obtained can be used in this state; however, a 5- to 30-μm-thick solder resist layer having therein arbitrary openings may be formed thereon to be used for multi-device surface mounting.

It is possible to use the state of FIG. 20(g) or 20(h) as a core board, and to form conductive-wiring layers alternately with dielectric resin layers on both the surfaces thereof by using an additive technique, a semi-additive technique, or subtractive technique. It was confirmed that, if the supporting substrate 71 is of a material having a significant rigidity other than the metal, such as glass, silicon and ceramics, the conductive-wiring layer 41 can be formed using a plating process by performing sputter-evaporation of conductive elements onto the seed layer, and the step of removing the supporting substrate 71 can employ polishing or peel-off using a releasing layer other than the etching, to effectively remove the supporting substrate 71.

With reference to FIGS. 21(a) to 21(j), a second example according to a second exemplary embodiment of the method of the present invention will be described. In FIG. 21(a), a conductive-wiring layer 72 comprised of 2- to 20-μm-thick nickel, and a conductive-wiring layer 73 comprised of 5- to 30-μm-thick copper were formed by a plating technique, similarly to FIG. 20(a), on a supporting substrate 71 comprised of 0.1- to 1.0-mm-thick copper. Thereafter, a 10- to 500-μm-thick dielectric resin layer 84 including a polyimide or epoxy ingredient was supplied using the vacuum laminator, as shown in FIG. 21(b), and was cured. Since the dielectric resin layer 84 exists directly under the functional device 10 even after removing the supporting substrate 71, it is possible to form the conductive-wiring layers 72 and 73 to have an arbitrary wiring shape such as BGA pads or flip-chip pads.

In a subsequent step, as shown in FIG. 21(e), the functional device 10 is adhered onto the dielectric resin layer 84 with an intervention of a 10- to 30-μm-thick adhesive layer 25 comprised of an epoxy-based die-attachment film. Thereafter, as shown in FIG. 21(d), dielectric resin layers 81 and 85 are supplied using a vacuum laminator and a vacuum press, as shown in FIG. 21(e), to encapsulate the circumference of the functional device 10 by the resin. At this stage, the number of dielectric resin layers used may be one or a plurality thereof, and is preferably designed so that warp of the circuit board after removal of the supporting substrate 71 is reduced, for achieving reliability of products and workability during manufacture thereof. It is also preferable to determine the arrangement of the dielectric resin layers in consideration of the adhesiveness with respect to the material of the functional device 10. If the dielectric resin layer 81 disposed on the side surface of the functional device 10 includes therein a non-fluidity material, such as glass cloth and aramid film, a space having a size equal to or 0.1 to 1 mm larger than the outer shape of the functional device 10 is provided within the dielectric resin layer 81 so that the non-fluidity material in the dielectric resin layer 81 does not damage the functional device 10 during the pressing.

The intermediate layer 24 comprised of SUS340 was effective to prevent a warp and improve the rigidity when the board had a smaller thickness. This intermediate layer 24 was subjected to a chemical etching to have therein openings having a size larger than the outer shape of vias at arbitrary positions and to have an opening having a size equal to or larger than the outer shape of the functional device 10, because a laser processing was performed in the subsequent steps for forming vias that connect together the conductive-wiring layer 73 and the conductive-wiring layer 31. In a subsequent step, as shown in FIG. 21(f), the electrode terminals 53 were exposed on the surface by using a grinding device, a buff-polishing device etc.

In a subsequent step, as shown in FIG. 21(g), 50- to 800-μm-diameter via-holes 67 were formed to reach an arbitrary conductive-wiring layer 73 in the vicinity of the supporting substrate 71 by using a CO2 laser or UV-YAG laser system. After washing the inside of via-holes 67 in a subsequent desmear processing, it is possible to perform electroless metal plating, as described with respect to FIG. 20. However, in the case where the via-holes have a height considerably larger than the inner diameter thereof, it was also possible to fill the via-holes 67 with copper by taking advantage of the fact that the supporting substrate 71 comprised of copper was a conductor, allowing the same to supply electric charge, and directly growing a Cu plating layer in the via-holes 67 from the side thereof near the supporting substrate 71. By metal plating the inside of via-holes 67 up to the height above the surface of dielectric resin layer 86, and by thereafter performing planarization of the surface of dielectric resin layer 86, the height of exposed vias near the dielectric resin layer 86 is the same as the surface of dielectric resin layer 86.

Upon performing the buff-polishing or grinding after plating the inside of via-holes 67, it is efficient to perform the same simultaneously with the grinding or buff-polishing the electrode terminals 53 in FIG. 21(g). If the plating of inside of via-holes 67 is to be performed simultaneously with formation of the conductive-wiring layer 31, as shown in FIG. 21(h), a desmear processing is used to wash the inside of via-holes 67, followed by forming the seed layer by an electroless plating or sputtering processing, and thereafter the inside of via-holes 67 is subjected to a metal plating. At this stage, it is also possible to form a conductive paste pattern on the seed layer by an ink-jet technique or printing technique. After formation of the conductive-wiring layer 31, the plating resist and an excessive portion of the seed layer is removed.

The subsequent process is similar to that of FIGS. 20(g) and 20(h), and includes removing the supporting substrate 71 comprised of copper in FIG. 21(i), and exposing the conductive-wiring layer 73 on the surface in FIG. 21(j). The circuit board thus obtained may be used in this state; however, a 5- to 30-μm-thick solder resist layer having therein arbitrary opening may be formed thereon and used for multi-device mounting. In this case, the solder resist layer may be formed only on one of the surfaces. It is possible to form the conductive-wiring layers alternately with the dielectric resin layers on both the surfaces, by using an additive process, a semi-additive process, or a subtractive process, with the state of FIGS. 21(i) and 21(j) being a core beard.

With reference to FIGS. 22(a) to 22(d), a third example according to a third exemplary embodiment of the method of the present invention will be described. As shown in FIG. 22(a), a 5- to 30-μm-thick epoxy-based resin is supplied as a dielectric layer configuring the solder resist layer 51 on a glass supporting substrate 71, an electroless copper plating is performed thereon, a pattern of conductive-wiring layer 41 comprised of copper is formed to a thickness of 5 to 30 μm, Thereafter, the plating resist is removed, and the electroless copper plating other than for the pattern of conductive-wiring layer 41 is removed by etching. In a subsequent process, similarly to the steps of FIGS. 21(c) to 21(h), supply of the dielectric resin layer 84, and mounting of the functional device 10 are performed, followed by resin-encapsulation of the circumference of functional device 10 by using the dielectric resin layers 81 and 84, and connecting together the conductive-wiring layers 31 and 41 with an intervention of the vias 67, thereby electrically connecting the functional device 10 to the circuit board of the present invention.

In a subsequent step, as shown in FIG. 22(b), the glass supporting substrate 71 is removed using a chemical liquid or mechanical polishing to expose the dielectric resin layer 51 on the surface, followed by forming openings 52 therein at the position corresponding to electrode terminals of a corresponding part mounted on the circuit board by using laser etc., to allow the same to function as the solder resist layer 51. A 5- to 30-μm-thick solder resist layer 51 having openings 52 therein is also formed on the opposite surface. Thereafter, as shown in FIG. 22(c), solder balls 60 are mounted within the openings 52 of one of the solder resist layers 51. A plurality of such circuit boards including the solder balls 60 were used as packages for stacking, by subjecting the same to reflow after performing an electric test on each of the packages, whereby it was possible to stack the plurality of circuit boards.

As compared to the case where a plurality of functional devices with different species are configured as a single circuit board, the configuration wherein a plurality of circuit boards each embedding therein a single functional device are stacked one on another has the advantage that each circuit board can be electrically tested at an intermediate stage to improve the product yield, although the overall volume is increased.

With reference to FIGS. 23(a) to 23(d), a fourth example according to a fourth exemplary embodiment of the method of the present invention will be described. As shown in FIG. 23(a), two circuit boards 201 and 202 which embed therein a functional device of the present invention and from which the supporting substrate is removed are stacked one on another, with an intervention of a 20- to 100-μm-thick adhesive layer 40 therebetween, such as a semi-cured thermo-setting resin or thermo-plastic resin having a pattern of vias 45 filled with paste including at least one species of element of Sn, Ag, Cu, Bi, Zn and Pb or conductive paste. In an alternative, as shown in FIG. 23(b), circuit boards 203 and 204 are opposed to each other which embed therein a functional device, in which the adhesive layer 40 is provided in advance to the circuit board 204 by using vacuum lamination, via-holes are formed using laser etc., and via-holes are filled with solder paste or conductive paste, and flow which the supporting substrate is not removed.

In a further alternative, as shown in FIG. 23(c), the circuit boards 203 and 204 of the present invention which embed therein the functional device and from which the supporting substrate is not removed are opposed to each other, with an intervention of adhesive layer 45 therebetween having a pattern of vias 45 filled with solder paste or conductive paste. At this stage, a ceramic part may be embedded within the circuit boards 201 and 202 embedding therein the functional device. A circuit board of the present invention and embedding therein a 0.6 mm×0.3 mm×0.3 mm-sized ceramic part was obtained by performing surface mounting the same on a conductive-wiring layer of the present invention, on which a circuit board was not yet mounted, by using conductive paste or plating, mounting a functional device within the dielectric resin layer, and thereafter connecting together the terminal electrodes of the functional device and the conductive-wiring layer right above the same.

Thereafter, bonding of the upper board and the lower of the present invention at the dielectric portion with an intervention of the adhesive layer was performed simultaneously with the conductive connection through the vias 45 by using a vacuum press, followed by a subsequent step of removing the supporting substrate, if it remains, by etching or polishing, to thereby obtain the circuit board wherein layers including the functional device are stacked one on another in a vertical direction, as shown in FIG. 23(d). It is possible to embed an aramid unwoven cloth, an aramid film, a glass cloth, and a silica film within the adhesive layer 40 as a contained material, for the purpose of reinforcement or higher-speed transmission. The circuit boards of the present invention to be used for the bonding may be bonded together after removing the supporting substrate therefrom. If at least one circuit board includes therein the supporting substrate, it has the function of uniformly pressing the entire area of boards during the vacuum pressing, to thereby achieve a higher reliability in the connection using the adhesive layer 40 and vias 45.

The adhesive layer 40 may also be obtained by forming 30- to 500-μm-diameter via-holes by using a laser processing or 80- to 500-μm-diameter via-holes by using a drill, in a state of the adhesive layer 40 where a 25- to 38-μm-thick protective film, such as PET (polyethylene terephthalate) and PEN (polyethylenenaphthalate), is bonded onto both the surfaces thereof, and thereafter performing printing with the solder paste or conductive paste by using the protective film as a mask to fill the via-holes, and removing the protective film. In addition, the printing may be performed, without using the protective film, while using a metal mask or screen mask, such as made of stainless steel and nickel.

The adhesive layer 40 may be provided in advance onto one of the functional-device-embedded circuit boards by using a laminating technique, thereafter forming via-holes on the conductive-wiring layer by using laser etc., and performing a printing process using the protective film, metal mask or screen mask. Removal of the protective film allows the adhesive layer 40 to bond together the two circuit boards by a subsequent vacuum pressing in the present invention. The circuit boards may be used in this state, or may be used for subsequent multi-device mounting after forming a 5- to 40-μm-thick solder resist layer. In addition, using the state of FIG. 23(d) as a core board, the conductive-wiring layers may be formed alternately with the dielectric resin layers on both the surfaces by using an additive process, semi-additive process, or subtractive process.

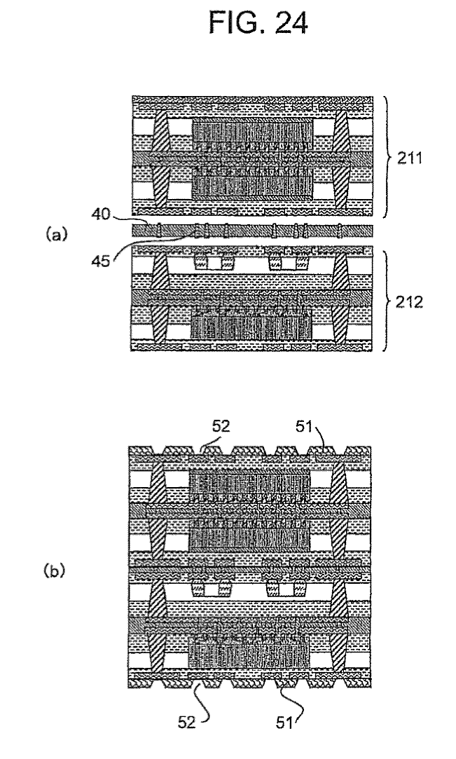

Two functional-device-embedded circuit boards of the present invention, as shown in FIG. 23(d), wherein the supporting substrate is attached onto one of the surfaces or is removed therefrom, are prepared, and are bonded together by a vacuum pressing technique etc., with an intervention of the adhesive layer 40 and vias 45 filled with solder paste or conductive paste, to obtain a further-multi-layered circuit board, as shown in FIG. 24(b). At this stage, the surface of the circuit boards 211 and 212 in contact with the adhesive layer 40 should be subjected in advance to removal of the supporting substrate, as a matter of course. The adhesive layer 40 can be provided using a laminating technique, a pressing technique etc., prior to the pressing. The supply of resin, and lamination or pressing used for coupling of the boards may be performed under an atmospheric ambient, similarly to the case of FIG. 23; however, a processing in vacuum is preferable because of capable of removing the voids remaining within the resin. It is possible to use the state of FIG. 24(b) as it is; however, it may be used for subsequent multi-device mounting after forming the solder resist layer 51 having therein arbitrary openings 52. In addition, it is possible to use the state of FIG. 24(b) as a core board, and conductive-wiring layers are formed alternately with the dielectric resin layers by using a semi-additive process or a subtractive process on both the surfaces thereof.

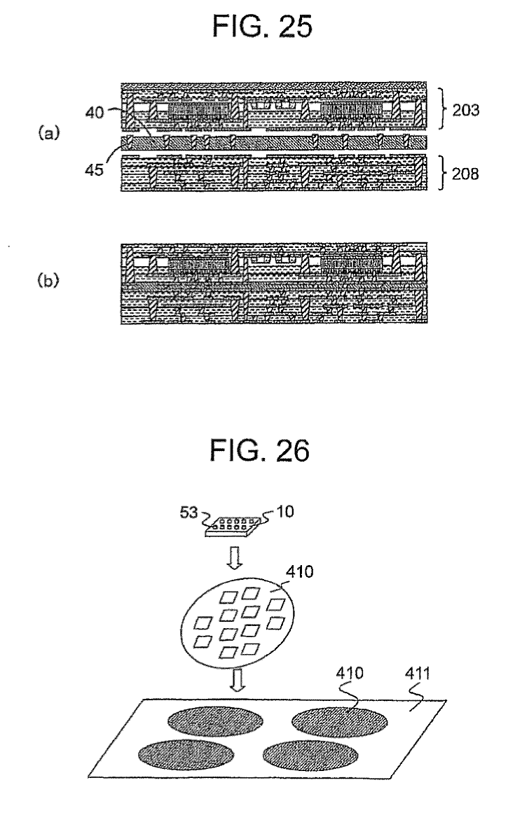

Note that the functional-device-embedded circuit board 203 of the present invention can be connected to a multi-layered circuit board 208 with an intervention of the adhesive layer 40 and vias 45 filled with solder paste or conductive paste, as shown in FIG. 25(a). In a subsequent step, the supporting substrate may be removed to obtain a multi-layered circuit board, as shown in FIG. 25(b), that is superior in a higher-speed electric performance and configured as a small-sized circuit board. At this stage, if the supporting substrate comprised of a metal or ceramics is attached onto the surface of the multi-layered circuit board 208 far from the adhesive layer 40, a uniform pressing can be achieved during the pressing, to obtain a circuit board having a higher reliability. As to the circuit board 203, it is preferable that the supporting substrate be also attached thereto during the pressing; however, the bonding may be performed after removing the supporting substrate. It is possible to use this state as it is; however, it is also possible to use the state of FIG. 25(b) as a core board and form the dielectric resin layers alternately with the conductive-wiring layers by using a semi-additive process or a subtractive process on both sides thereof.

With reference to FIG. 26, a fifth example according to a fifth exemplary embodiment of the method of the present invention will be described. Using a plurality of circuit boards 410 of the present invention embedding therein a functional device comprised of a Si substrate and embedding the circuit boards of the present invention in a larger-sized board 411, at least one conductive-wiring layer and at least one dielectric layer were formed on one or both the of the circuit boards that are used as the core layer. At this stage, the design was such that the conductive-wiring layer for which the terminal pitch thereof is enlarged by connecting thereto the electrode terminals of the functional device 10 is provided on the surface of the circuit boards 410. This facilitated the electric test of the circuit boards 410 before embedding the same in the larger-sized board 411. By embedding only 8-inch circuit boards 410 which are judged as a non-defective device in a 500 mm×600 mm large-sized board 411, the product yield can be improved, and the fabrication cost may be reduced due to processing for the large-sized board.

Since the conductive-wiring layer is directly connected from the electrode terminals 53 of the embedded functional device 10, a semi-additive technique that is capable of providing a finer circuit pattern was used to form the circuit boards 410. However, if it is possible to use a subtractive technique that provides a lower cost and a less finer circuit pattern, in a wiring processing for a 500 mm×600 mm large-sized board 411, a fabrication process performed on two separate sites is efficient in the work, to thereby improve the mass-productivity and achieve a higher product yield and a lower cost.

With reference to FIG. 33, a sixth example according to a sixth exemplary embodiment of the method of the present invention will be described. First, as shown in FIG. 33(a), a board was prepared wherein a Ni conductive-wiring layer 152 and a Cu conductive-wiring layer 153 were consecutively formed on a copper supporting plate 151. Subsequently, as shown in FIG. 33(b) a functional device 10 was mounted thereon, with an intervention of the adhesive layer 25, so that the electrode terminals 53 were disposed upward, after a protective layer 154, if needed, was provided on the surface of the functional device on the circumference of the electrode terminals. In a subsequent step, as shown in FIG. 33(c), dielectric resin layers 81, 84 and 85 were supplied to embed therein the functional device 10, and thereafter, the vias were formed to reach the conductive-wiring layer 153 from the surface opposing the supporting substrate 151 by using laser and desmear.

Thereafter, in the process of FIG. 33(e), a seed layer was formed on the entire surface in the order of Ti/Cu from the side of dielectric resin by an electroless plating or sputtering technique. In a subsequent step, as shown in FIG. 33(f), plating copper was formed on the entire surface so that the inside of via-holes 67 was filled with a conductor layer 521. In a subsequent step of FIG. 33(g), buff-polishing was performed after a copper etching so that the embedded electrode terminals 53 and the exposed surface of vias 522 were arranged on the same plane, followed by forming vias 501. Thereafter, as shown in FIG. 33(h) Ti/Cu sputtering was performed again to form a seed layer 511, followed by forming a plating resist pattern, forming a conductive-wiring layer 31 by plating etc., and removing the plating resist and removing the seed layer in an area other than for the conductive-wiring layer 31. In a subsequent step, as shown in FIG. 33(i), the copper supporting plate 151 and Ni conductive-wiring layer 152 were removed by buff-polishing, to obtain the circuit board 115 shown in FIG. 29.

Here, in the step shown in FIG. 33(g), the vias 522 and electrode terminals 53 can be observed simultaneously, whereby a superior positioning accuracy is obtained during the wire patterning using exposure, thereby improving the product yield. Since the seed layer existed on the entire interface with respect to the top portion, bottom portion and side surface of the vias 501, a higher strength could be obtained in the event of a three-dimensional stress applied thereto, thereby achieving a higher reliability and a longer lifetime.

With reference to FIG. 34, a seventh example according to a seventh exemplary embodiment of the method of the present invention will be described. First, as shown in FIG. 34(a), a board was prepared wherein conductive-wiring layers 152 and 153 were layered in this order on a supporting plate 151. Next, as shown in FIG. 34(b), a functional device 10 is mounted on this board, with an intervention of the adhesive layer 25, so that the electrode terminals 53 are disposed upward, and so that a protective layer 154, if necessary, is formed on the surface of the functional device on the circumference of the electrode terminals. In a subsequent step, as shown in FIG. 34(c), dielectric resin layers 81, 84 and 85 are supplied to embed therein the functional device 10, and as shown in FIG. 34(d), vias are formed to reach the conductive-wiring layer 153 from the surface opposing the supporting plate 151 by using laser.

Thereafter, in the step of FIG. 34(e), a Cu seed layer is formed on the entire surface by an electroless plating. In a subsequent step, as shown in FIG. 34(f), an electrolytic plating is performed on the entire surface so that the inside of via-holes 67 is filled with a conductor layer (Cu layer) 521. In this case, if the depth of vias is about 120 μm for the diameter of vias being 100 μm, and if the thickness of conductor layer 521 is as thin as about 20 μm, the vias are not completely filled to form a void in the top central portion thereof, unlike the manufacturing process shown in FIG. 33. Thus, in a subsequent step, as shown in FIG. 34(g), epoxy-based resin 523 was supplied to the void by a printing technique. Note that the resin 523 is not limited to epoxy. At this stage, it is preferable to use a vacuum printing machine, which prevents the resin within the vias from including the void to thereby form superior vias. Thereafter, in the step of FIG. 34(h), a copper etching and a subsequent buff-polishing was performed so that the embedded electrode terminals 53 and the exposed surface of vias were located on a single plane. Subsequently, in the step of FIG. 34(i), a seed layer 511 is formed by sputtering, a plating resist pattern is formed, a conductive-wiring layer 31 is formed by copper plating, and the seed layer is removed in the area other than for the conductive-wiring layer 31 together with the plating resist. In a subsequent step, as shown in FIG. 34(j), the supporting plate 151 and conductive-wiring layer 152 are removed by etching, grinding etc., to obtain the circuit board 116 shown in FIG. 30.

Here, in the step shown in FIG. 34(i), since the vias 502 and electrode terminals 53 can be observed simultaneously, a superior positioning accuracy can be obtained during patterning of the conductive wiring using exposure, to thereby improve the product yield. In addition, since the seed layer exists on the entire interface with respect to the top portion, bottom portion and side surface of the vias, the vias 502 maintain a higher strength in the event of three-dimensional stress applied thereto, to thereby improve the reliability. Further, as compared to the fabrication process shown in FIG. 33, the conductive layer provided on the entire surface in the step of FIG. 34(f) has a smaller thickness in the present exemplary embodiment, whereby the time length needed for grinding or etching the electrode terminals 53 and vias can be reduced.

With reference to FIG. 35, an eighth example according to an eighth exemplary embodiment of the method of the present invention will be described. First, respective steps shown in FIGS. 34(a) to 34(d) are performed similarly to FIG. 33. Subsequent to those steps, as shown in FIG. 34(e), an AD process is performed to form the conductor layer 521, without forming the seed layer, by impinging metallic powder having a grain diameter of 1 μm or smaller at a high speed, thereby filling the via-holes 67 formed in advance with the metallic powder. In a subsequent step, as shown in FIG. 35(g), the seed layer 511 is formed, and thereafter the conductive-wiring layer is formed. In a subsequent step, as shown in FIG. 35(h), the supporting plate and conductive-wiring layer 152 are removed by etching, grinding etc., to obtain the circuit board 117 shown in FIG. 31.

Here, the AD process achieves deposition of a thickness up to several millimeters within a shorter period of time as compared to the plating. Thus, the AD process can significantly reduce the fabrication time length, and allows the inside of conductor in a portion of the vias 503 having a smaller inner diameter and disposed near the conductive-wiring layer 153 to have a finer metallic structure with smaller Cu crystal grains, and allows the inside of conductor in a portion of the vias 503 having a larger inner diameter and disposed near the conductive-wiring layer 31 to have larger Cu crystal grains compared to the portion near the wiring layer 153, thereby improving the reliability of products. Further, since an intensive energy is added to the bottom of vias 503, it is possible to obtain a superior bonding strength at the bottom of vias to thereby improve the reliability.

With reference to FIG. 36, a ninth example according to a ninth exemplary embodiment of the method of the present invention will be described. First, in the step shown in FIG. 36(a), conductive-wiring layers 152 and 153 are formed on a supporting plate 151. Thereafter, in the step shown in FIG. 36(b), plating resist is supplied up to a thickness of about 20 μm, and in order to form, on the wiring 153, the vias that connect together the top interconnections and bottom interconnections of the functional device, a hole pattern is formed on the location of posts by using exposure and development. Thereafter, in this process, plating is performed to a thickness of about 30 to 40 μm so that the thickness of plating is larger than the thickness of resist, to thereby obtain mushroom-shaped posts 510. At this stage, if the supporting plate 151 is of copper, the electric power can be supplied through the supporting plate 151. In a subsequent step, as shown in FIG. 36(c), the resist is removed, and as shown in FIG. 36(d), a functional device 10 is mounted. In a subsequent step, as shown in FIG. 36(e), the functional device 10 is embedded within the dielectric resin layers 81, 84 and 85. At this stage, the mushroom-shaped posts 510 are also embedded simultaneously. Thereafter, the vias are formed by laser.

In the step shown in FIG. 36(f1), the seed layers 511, 512 and 513 were formed by sputtering in the order of Ti/Cu so that the seed layers were configured as a single common seed layer, and the conductive-wiring layer (plating conductive-wiring layer) 3 was formed using a plating resist. In the step shown in FIG. 36(f2), electric power was supplied through the copper supporting plate 151, to form the conductor of via-plugs 505 by a copper plating, and thereafter, the electrode terminals 53 of the embedded functional device 10 were grinded (for exposure of top) using a buff-polisher, and at the same time the exposed surface of via-plugs 505 was allowed to have the same plane (at an accuracy of about ±5 μm). In this step, the seed layer 511 was provided only onto the top portion of via-plugs 505, and the conductive-wiring layer 31 was formed by a semi-additive process using plating resist. In the step shown in FIG. 36(f3), via-plugs 506 including seed layers 513, 511 and 512 at the bottom portion, top portion and side surface thereof were formed, after the laser processing, similarly to the steps shown in FIGS. 33(e) to 33(i). In the step shown in FIG. 36(f4), performing the steps similar to those shown in FIGS. 34(c) to 34(i), resin 508 was embedded in the top center portion of vias, and via-plugs 507 including the seed layers 513, 511 and 512 at the bottom portion, top portion and the side surface thereof, could be formed together with the other conductor portions.

Since the mushroom-shaped posts 510 are formed in advance to be embedded within the resin irrespective of any techniques employed, the post portion embedded within the resin can be observed more clearly than the conductive-wiring layer 73 during the later laser processing for forming the via-holes. This provides a superior recognition of position with a higher accuracy, to raise the yield of products. In addition, presence of the pileus structure portion on the mushroom-shaped posts 510 provides a higher strength and a higher reliability as described before. Further, the smaller height of vias formed by laser processing reduces the aspect ratio of vias, thereby facilitating removal of residues at the bottom of vias during patterning of resist, and since the plating liquid in the plating bath had a higher fluidity at the bottom of vias, a reliable conductive-wiring layer 31 could be obtained.

In one exemplary embodiment of the present invention, a plurality of functional devices are connected together with a shorter distance therebetween, thereby achieving a superior high-speed electric performance. Another object of the present invention is to allow the functional-device-embedded board to be used as a circuit board having superior electric properties as well as a package due to inclusion of narrow-pitch interconnections of the top and bottom surfaces that are connected together by vias.

One embodiment of the present invention is to manufacture a highly-integrated functional-device-embedded circuit board due to three-dimensional integration of the functional devices. Another object of the present invention is to allow the conductive-wiring layer of the front and rear surfaces of the circuit board to have a uniform height and be located within the same plane, thereby improving the connection reliability between the circuit board and the electronic device.

One embodiment of the present invention is to achieve a manufacturing process having a higher reliability, even for the case of a thin and fragile functional device, without a damage thereon occurring during the fabrication stages. Another object of the present invention is to alleviate the stress caused by a difference in the thermal coefficient of expansion between the functional device and the material of the heat sink to thereby achieve a higher reliability. Another object of the present invention is to prevent a crack within the dielectric resin, conductive wiring and functional device that may result from a stress occurring in the thickness direction and board-surface direction depending on the thermal coefficient of expansion between the functional device and the peripheral dielectric resin layer in the functional-device-embedded circuit board and the area of the conductive-wiring layers formed on the front and rear surfaces, and to prevent peel-off at the interface between at least two members of the dielectric resin, conductive wiring and functional device, thereby achieving a higher reliability. Another object of the present invention is to improve the positional accuracy of the functional device and intra-board conductive wiring, raise the product yield, form a higher-specification wiring layer and reduce the size of circuit board.

One exemplary embodiment of the present invention is to planarize the conductive wiring disposed on the front and rear surfaces of the circuit board and the dielectric layer.

One exemplary embodiment of the present invention is to provide three-dimensional connection between a plurality of functional devices with a shorter distance therebetween, thereby achieving a superior high-speed electric performance. For inducing the heat radiation from the functional device, the first conductive-wiring layer may be configured as a heat-radiating patterned interconnection, which may be arbitrarily designed to alleviate the stress occurring due to the difference in the thermal coefficient of expansion between the wiring material of the board and the functional device, to achieve a higher reliability of the products. Since the outer shape of the functional-device-embedded board is larger than the outer shape of the functional device, the wiring rule of the electrode terminals of the functional device can be expanded at the front and rear surfaces thereof, thereby achieving a superior workability and reliable mounting during connection between the circuit board and the functional device.

In a preferred embodiment of the first aspect of the circuit board of the present invention, patterned interconnections in the second wiring layers and the surface of the electrode terminals are connected together with an intervention of a seed layer. The adhesive strength between the patterned interconnections of the second wiring layer and the electrode terminal is improved to thereby improve the reliability of the products. It is preferable that seed layer include at least one element selected from the group consisting of Ti, W, Cr, Pt, Au, Cu, Ni, Ag, Sn and Pd.

In a preferred embodiment of the first aspect of the circuit board the present invention, a third dielectric layer intervenes at least a part of a gap between the second dielectric layer and the second conductive-wiring layer. The adhesive strength between the second dielectric layer and the second conductive-wiring layer can be increased.

In a preferred embodiment of the first aspect of the circuit board the present invention, conductor vias that connect together patterned interconnections of the first conductive-wiring layer and patterned interconnections of the second conductive-wiring layer have a larger cross-sectional area at a portion in a vicinity of the second conductive-wiring layer than at a portion in a vicinity of the first conductive-wiring layer. In the step of metal-plating the inside of via-holes that receives therein conductor vias, observation of plating part is facilitated, and thus judgment between a superior plated state and a defective portion is facilitated, to improve the quality of products.

In a preferred embodiment of the first aspect of the circuit of the present invention, a configuration may be employed wherein the seed layer covers a side of the conductor vias that connect together the first conductive-wiring layer and the second conductive-wiring layer, and is formed between the conductor vias and the first conductive-wiring layer. For example, the conductor vias disposed near the side surface of the functional device and connecting together the first conductive-wiring layer and the second conductive-wiring layer are provided with the seed layer at the bottom portion, side surface and top portion of the conductor vias. As a result, after the functional device is embedded within the board, the seed layer that is formed against the deformation caused by the stress occurring in the thickness direction of the board due to the difference in the thermal coefficient of expansion between the functional device and the surrounding dielectric resin layer as well as the difference existing in the thickness or area between the first conductive-wiring layer and the second conductive-wiring layer increases the adhesive strength with respect to the surrounding resin and prevents peel-off at the interface with respect to the resin. In addition, the seed layer formed between the bottom portion of conductor vias and the first conductive-wiring layer and/or between the top portion of vias and the second conductive wiring layer as well as the side surface of the vias maintains a larger adhesive strength. Thus, it is possible to prevent a disconnection or a crack within the dielectric resin in the event of a deformation such as a warp, thereby achieving a higher reliability of products.

In the first aspect of the circuit board of the present invention, a configuration may be employed wherein the seed layer is formed between time conductor vias and the second conductive-wiring layer.

In the first aspect of the circuit board of the present invention, a configuration may be employed wherein a resin layer is embedded in a central surface portion of the conductor vias in a vicinity of the second conductive-wiring layer. In this case, it is possible to allow the thermal coefficient of expansion of conductor vias to be close to that of the dielectric resin layer existing outside the conductor vias, thereby improving the reliability.

In the first aspect of the circuit board of the present invention, a configuration may be employed wherein the conductor vias each include a conductor post including a uniform-diameter portion and a larger-diameter portion having a lager diameter than the uniform-diameter portion, and a via-plug formed on the conductor post, and the seed layer is formed between the via-plug and the second conductive-wiring layer. For example, the vias connecting together the first conductive-wiring layer and the second conductive-wiring layer and located near the side of the embedded functional device may include a pileus portion of a mushroom shape in the middle portion of vias, and the pileus portion may extend in the horizontal direction as a wedge toward the inside of the dielectric resin layer, thereby increasing the adhesive strength in the thickness direction between the conductor vias and the dielectric resin layer in the event of deformation and stress of warp occurring in the functional-device-embedded board even without forming the seed layer on the side surface of the vias. Thus, it is possible to prevent a disconnection in the vias, and to thereby provide a higher reliability for the products. On the other hand, for conductor vias having a trapezoidal cross-sectional shape, there is a possibility that peel-off at the interface between the side surface of vias anti the dielectric resin may occur unless reinforcement of the adhesive strength between the side surface of vias and the dielectric resin layer is provided by the seed layer.

In the first aspect of the circuit board of the present invention, a configuration may be employed wherein the conductor vias have crystal grains larger at a portion in a vicinity of the first conductive-wiring layer than at a portion in a vicinity of the second conductive-wiring layer. For example, the conductor vias may be such that a fine metal structure having smaller crystal grains is formed at a smaller-diameter portion of the conductor vias near the first conductive-wiring layer, the crystal grains are larger at a larger-diameter portion near the second conductive-wiring layer compared to the portion near the first conductive-wiring layer, and the seed layer is formed at least between the second conductive-wiring layer and the conductor vias. In this case, the size of crystal grains exerts an influence on the hardness of the structure or expansion of the alloy configuring the conductor vias. Thus, a smaller-diameter portion near the first conductive-wiring layer has a larger strength and a higher hardness. In addition, the larger-diameter portion near the second conductive-wiring layer has larger crystal grains and an expansion property, thereby alleviating the stress in the event of deformation of the board, such as a warp, occurring due to incorporation of the functional device. Therefore, the stress applied onto the interface can be alleviated even without forming the seed layer on the interface between the side surface of the conductor vias and the dielectric resin layer, thereby preventing a disconnection at the vias to improve the reliability of products.

In the first aspect of the circuit board of the present invention, a configuration may be employed wherein a part of the patterned interconnections in the second conductive-wiring layer includes one or a plurality of element selected from the group consisting of Cu, W, Cr, Pt, Ni, Zn, Fe, Al, C, Mn, Ir, Ti, N and O. In addition, a configuration may be employed wherein a part of the patterned interconnections in the second conductive-wiring layer includes one or a plurality of elements selected from the group consisting of Mg, Mn, Ti, Sr, Ba, Ca, Zn, Al, Ta, Si, Au, Zr, Nb, Hf, Pb, Bi, N and O. Further, a configuration may be employed wherein a part of patterned interconnections in the second conductive-wiring layer configures an inductor that has a spiral shape or meander shape. It is possible to reduce the volume of the passive elements embedded or surface-mounted in the board, and to obtain superior electric properties.

The first aspect of circuit board of the present invention may further include, inside of the circuit board, an intermediate conductive-wiring layer including at least one species of element selected from Fe, Ni, Cr, Co, Cu, Sn, Si and Al. The intermediate conductive-wiring layer can increase the strength of the circuit board. Use of the intermediate conductive-wiring layer as a grounding layer achieves superior electric properties. Further, the intermediate conductive-wiring layer can increase the heat radiation capability of the circuit board.

The first aspect of the circuit board of the present invention may further include a plurality of species of dielectric resin layers within the circuit board. Provision of the separate dielectric resin layers allows use of a combination of a soft resin and a hard resin, combination of a higher heat-resistant resin and a lower heat-resistant resin or combination of an expensive resin and an inexpensive resin, thereby achieving a lower cost as well as improvement of reliability of products.

In the first aspect of the circuit board of the present invention, a configuration may be employed at least one of the first and second conductive-wiring layers includes a plurality of the conductor layers, and a combination of conductor layers connected together by a conductor via that connects together the conductor layer of the first conductive-wiring layer and the conductor layer of second conductive-wiring layers include a plurality of combinations. In addition, the second conductive-wiring layer may include a plurality of the conductor layers, and one of the conductor layers of the second conductive-wiring layer that is connected to the first conductive-wiring layer by a conductor via is farther than the electrode terminals of the functional device. Further, at least one of the first and second conductive-wiring layers may include three conductor layers or more, and one of the conductor layers is connected by a conductor via to another of the conductor layers other than the other of the conductor layers nearest to the one of the conductor layers.

The first aspect of the circuit board of the present invention may further embed therein an electronic part. In the first aspect of the circuit board of the present invention, the circuit board may embed therein a plurality of functional devices that are arranged in at least one of directions parallel to a thickness direction and a board-surface direction. It is possible to reduce the line length between these functional devices, thereby achieving a circuit board having a higher-speed electric property. In addition, employment of combination of radio elements and logic and/or memory devices may achieve a multi-function circuit board. Since the functional device is not exposed on the surface, workability during the conveyance can be improved.

If the circuit board embeds therein a plurality of functional devices that are arranged in at least one of directions parallel to a thickness direction and a board-surface direction, it is preferable that adjacent two of the functional devices arranged parallel to the thickness direction of the circuit board be arranged such that the electrode terminals of one of the adjacent two oppose the electrode terminals of the other. For example, after an LSI is subjected to flip-chip bonding, the distances of LSI measured from both the functional devices are made equal to each other, thereby improving the connection reliability. In this case, a conductive paste or lead-free solder paste including at least one species of element selected from the group consisting of Sn, Ag, Cu, Bi, Zn and Pb may connect together the electrode terminals of the one of the adjacent two and the electrode terminals of the other, and may connect together one of the conductive-wiring layer connected to the one of the adjacent two and another of the conductive-wiring layer connected to the other.

In the first aspect of the circuit board of the present invention, the electrode terminals of the functional device may be connected to one of the conductive-wiring layers in the circuit board by a conductive paste or lead-free solder paste including at least one species of element selected from the group consisting of Sn, Ag, Cu, Bi, Zn and Pb.

In a preferred embodiment of the present invention, a solder resist layer having therein an opening is formed on a surface of the second conductive-wiring layer. It is possible to prevent a short-circuit failure caused by reflow of lead-free solder or melting of solder balls upon mounting another functional device.

In accordance with the first aspect of the circuit-board manufacturing method of the present invention, it is possible to perform in succession the processings of forming the first conductive-wiring layer, mounting the functional device, and forming the conductive-wiring layer, to thereby reduce the cost. By forming the first conductive-wiring layer on the supporting substrate, and mounting the functional device thereon, application of pressure during the mounting does not deform the supporting substrate to prevent bending of the functional device, to thereby prevent damage on the functional device itself. Removal of the supporting substrate to expose the first conductive-wiring layer on the rear surface of the board allows the surface of the first conductive-wiring layer to be formed on the same plane as or lower than the surface of the dielectric resin layer, whereby the surface of the dielectric resin layer plays a roll of the solder resist to obviate forming of the solder resist layer. The height of the conductive-wiring layer formed on the supporting substrate is uniform, to achieve a higher connection reliability during mounting a semiconductor device etc.

In the first aspect of the circuit-board manufacturing method of the present invention, the covering step may include the step of simultaneously covering a metal layer including at least one species of element selected from the group consisting of Fe, Ni, Cr, Co, Cu, Sn, Si and Al.

A preferred embodiment of the first aspect of the circuit-board manufacturing method of the present invention further includes the step of forming a seed layer including at least one species of element selected from the group consisting of Ti, W, Cr, Pt, Au, Cu, Ni, Ag, Sn and Pd prior to the step of funning the conductive-wiring layer, and the step of patterning the seed layer subsequent to the step of forming the conductive-wiring layer.

A preferred embodiment of the first aspect of the circuit-board manufacturing method of the present invention further includes the steps of forming a releasing layer on the supporting substrate, prior to the step of forming the first conductive-wiring layer.

In the first aspect of the circuit-board manufacturing method of the present invention, the supporting substrate may include at least one species of element selected from the group consisting of copper, iron, nickel, chromium, aluminum, titanium, silicon, nitrogen, oxygen and carbon.

In a preferred embodiment of the first aspect of the circuit-board manufacturing method oldie present invention, the step of forming the conductive-wiring layer includes the steps of consecutively forming the first and second conductor layers, and, subsequent to the step of removing the supporting substrate, removing the first conductor layer to expose the second conductor layer.

The first aspect of the circuit-board manufacturing method of the present invention may further include, subsequent to the step of forming the first conductor layer, the steps of embedding the functional-device-embedded circuit board in another supporting substrate, and forming another conductive-wiring layer on the another substrate.

The first aspect of the circuit-board manufacturing method of the present invention may further include the step of connecting a terminal of an electronic part to the conductive-wiring layer by using solder including at least one species of element selected from the group consisting of Sn, Ag, Cu, Bi, Zn and Pb.

The first aspect of the circuit-board manufacturing method of the present invention may further include, prior to the step of forming removing the supporting substrate, the steps of forming a via-hole to reach the supporting substrate from the conductive-wiring layer, and plating an inside of the via-hole.

A configuration may be employed wherein the first aspect of the circuit-board manufacturing method of the present invention further includes, prior to the step of forming the conductive-wiring layer, the step of forming a via-hole to reach the supporting substrate from the surface of the dielectric resin layer, and plating an inside of the via-hole.

A configuration may be employed wherein the first aspect of the circuit-board manufacturing method of the present invention further includes the step of filling the plated via-hole with a conductor by using an AD (aerosol deposition) technique. For example, conductor particles are bonded using an A/D technique onto the inside of via-holes located on the side of the area wherein the functional device is embedded, to thereby form conductor vias. In this ease, the functional device is embedded in the dielectric resin layer, followed by forming via-holes by using laser, removing the residues of dielectric resin at the bottom portion by using desmear processing, and thereafter depositing metal particulates, such as Cu, Au and Ni, in a vacuum ambient by using the AD process. Here, the AD process can deposit a thicker film as compared to the plating. Thus, the fabrication time length can be drastically reduced, and a fine metal structure having smaller crystal grains is formed within a smaller-inner-diameter portion of the conductor of vias near the first conductive-wiring layer, whereas larger crystal grains are formed in the larger-inner-diameter portion near the second conductive-wiring layer as compared to the portion near the first conductive-wiring layer. This improves the reliability of products.

The first aspect of the circuit-board manufacturing method of the present invention may further include, prior to the step of removing the part of the dielectric resin layer, the steps of forming a via-hole in the dielectric resin layer, forming a seed layer on a bottom portion, a side surface and a top portion of the via-hole and the surface of the dielectric resin layer, forming a conductor via by plating an inside of the via-hole, and grinding the electrode terminals of the functional device and a top surface of the conductor via. For example, via-holes penetrating from the first dielectric layer that isolates patterned interconnections of the outermost layer of the first conductive-wiring layers from one another to the second dielectric layer that isolates the electrode terminals of the functional device from one another are formed in the dielectric resin layer by laser irradiation prior to forming the second dielectric resin layer. Thereafter, the seed layer is formed on the bottom portion, side surface and top portion of the via-holes and the surface of the dielectric resin layer, followed by plating onto the entire surface without forming resist thereby Cu-plating the surface of board and the inside of via-holes and form conductor vias. Subsequently, the top surface of vias and the electrode terminals of the embedded functional device are grinded at the same time. Thereafter, the top surface of the conductor vias and the electrode terminals of the functional device are connected together after forming the seed layer. Thus, the seed layer is formed on the bottom portion, side surface and top portion of vias. As a result, the conductor vias have a strong adhesive property at the interface with respect to the resin and the overlying interconnections, against the stress in the thickness direction that is caused, as one of factors, by incorporation of the functional device in the board, thereby achieving a superior reliability of products. Note that vias may be ones referred to as filled vias wherein a plating metal is embedded, are not limited thereto, and may be ones referred to as conformal vias obtained by metal-plating only the bottom portion and side surface of vias and filling the central portion thereof with resin after the plating. If laser vias are formed in a dielectric resin layer having a thickness equivalent to or larger than that of an ordinary functional device, the aspect ratio (height/inner diameter) of vias is large. If the exposure and development is performed in this structure after applying a resist for a patterned plating, it is difficult to remove residues of the plating resist existing on the bottom portion of vias, whereby the plated state of the bottom portion has a poor reliability. On the other hand, in the manufacturing method of the present invention, the resist is not used because of plating the entire surface for the purpose of plating the inside of vias, to thereby improve the reliability.

In the first aspect of the circuit-board manufacturing method of the present invention, a configuration may be employed wherein the step of forming the conductor vias uses an entire-area plating, printing, or AD process.

In the first aspect of the circuit-board manufacturing method of the method of the present invention, a configuration may be employed wherein the method further includes the step of prior to the step of mounting the functional device, forming a conductor post on the first conductive-wiring layer; and subsequent to the step of covering the functional device, forming a via-hole in a portion of the dielectric resin layer covering the conductor post, and forming a via-plug connecting to the conductor post within the via-hole. For example, mushroom-shaped plating posts (conductor post) are formed at the location wherein the conductor vias are to be formed near the side of functional device on the first conductive-wiring layer obtained by plating onto the supporting substrate before mounting the functional device, followed by mounting the functional device to be embedded within the dielectric resin layer, and forming via-holes by laser irradiation onto the top portion of the conductor posts embedded within the dielectric resin layer. Thereafter, it is possible to perform electroless plating and subsequent electrolytic plating, or stacking plating layers within the via-holes by supplying power from the supporting substrate, to form via-plugs connected to the conductor posts, whereby the conductor vias connecting together the first conductive-wiring layer and the second conductive-wiring layer are formed. In this case, formation of the conductor posts in advance allows a portion of the conductor posts embedded within the dielectric resin layer to be observed more clearly than the first conductive-wiring layer upon later laser irradiation for forming the via-holes. Thus, a superior accuracy can be obtained in recognition of the position, to thereby improve the product yield. The pileus portion formed on the conductor posts increases the strength and improves the reliability as described before.

In the second aspect of the circuit-board manufacturing method of the present invention, at least one of two functional-device boards may be a functional-device board that is prior to removal of the supporting substrate, and the method may further include the step of removing the supporting substrate that is not removed. In addition, the conductive paste or lead-flee solder paste may include at least one species of element selected from the group consisting of Sn, Ag, Cu, Bi, Zn and Pb.

In the third aspect of the circuit-board manufacturing method of the present invention, the conductive paste or lead-free solder paste may include at least one species of element selected from the group consisting of Sn, Ag, Cu, Bi, Zn and Pb.

In the circuit-board manufacturing method of the present invention, at least one of the first conductive-wiring layer and the conductive-wiring layer may be covered by a solder resist layer having therein an opening.

A semiconductor device, SAW filter or thin-film functional device etc. formed and wired on Si, GaAs, LiTaO3, LiNbO3, quartz etc., a chip part such as condenser, resistor, inductor etc., and a device wired on a printed circuit board and flexible substrate may be preferably used as the functional device in the present invention, which is not limited thereto. Silicon, glass, ceramics, such as alumina, glass ceramics, titanium nitride and aluminum nitride, metal such as copper, stainless steel, iron, and nickel or organic resin such as thick polyimide may be used for the supporting substrate, which is not limited thereto.

The types of vias used in the present invention include, if plating conductor metal, such as gold, silver, copper and nickel is to be used, conformal vias obtained by forming via-holes in a dielectric resin layer by using laser, desmear processing using chemical liquid for removing resin residues within the vias, and subsequently forming a seed layer by using electroless plating or evaporation of Ti, W, Cr, Pt, Au, Cu, Ni, Ag, Sn, and filled vias obtained by entirely filling the inside of via-holes with plating metal, which are preferably used without limitation. The technique for forming the via-holes may preferably use UV-YAG and CO2 laser etc., without limitation thereto. The technique for exposing the electrode terminals from the dielectric resin layer may be such that a releasing layer is provided in advance on the electrode terminals upon incorporation of the functional device, and the releasing layer is removed by peel-off after curing the resin, or the resin embedding therein the functional device is cured and then grinding is performed to expose the internal electrode terminals on the board surface. Use of photosensitive type for the dielectric resin layer allows the via-holes to be formed by exposure and development.

A portion of the conductive-wiring layer exposed on the surface in the present invention may be preferably formed by performing electroless plating, electrolytic plating, printing treatment or reflow, even if the conductive-wiring layer is formed by, for example, copper plating, such as copper, nickel, gold, silver, Sn—Ag solder. However, the material of surface of the conductive-wiring layer surface is not limited thereto.

The electrode terminals formed on the functional device in the present invention may be ones referred to as cylindrical posts comprised of copper, nickel, gold, silver etc., or ball-like ones such as Sn—Ag solder, which are preferably used, without limitation thereto.

The outermost surface of the circuit board of the present invention may be preferably provided with a solder resist layer including therein openings at the desired positions in order for restricting a portion of the conductive-wiring layer from being exposed on the surface, preventing oxidation of interconnections, and preventing a short-circuit failure between the conductive-wiring layers during mounting using solder. A portion of the conductive-wiring layer exposed from the openings is subjected to an electroless plating, electrolytic plating, or printing treatment using copper, nickel, gold, silver and Sn—Ag solder, thereby forming a conductive-wiring layer having a superior oxidation resistance or a superior wettability with respect to solder.

Note that an electronic part obtained by dicing the circuit board of the present invention into a plurality of pieces and embedding the piece in another circuit board or functional device, and a board further embedding therein the circuit board fall within the scope of the claims of the present invention.

While the invention has been particularly shown and described with reference to exemplary embodiment thereof, the invention is not limited to these embodiments and modifications. As will be apparent to those of ordinary skill in the art, various changes may be made in the invention without departing from the spirit and scope of the invention as defined in the appended claims.

This application is based upon and claims the benefit of priority from Japanese patent applications No. 2007-93083 filed on Mar. 30, 2007 and No. 2008-2159 filed on Jan. 9, 2008, the disclosure of which is embedded herein in its entirety by reference.

1. A circuit board comprising: at least one functional device; a wiring board embedding therein said functional device; and first and second wiring layers disposed on front and rear surface portions, respectively, of said wiring board to sandwich therebetween said functional device and each including at least one conductor layer, wherein:
each of patterned interconnections in an outermost conductor layer of said first conductive-wiring layer is exposed, and a first dielectric layer that isolates said patterned interconnections in said outermost layer from one another has a surface protruding from a surface of said patterned interconnections; and
patterned interconnections in said second wiring layer are connected to respective electrode terminals of said functional device, and at least a part of a surface of a second dielectric layer isolating said electrode terminals from one another and at least a part of a surface of said electrode terminals are substantially in a same plane.

2. The circuit board according to claim 1, wherein said patterned interconnections in said second wiring layers and a surface of said electrode terminals are connected together with an intervention of a seed layer.

3. The circuit board according to claim 2, wherein said seed layer comprises at least one element selected from the group consisting of Ti, W, Cr, Pt, Au, Cu, Ni, Ag, Sn and Pd.

4. The circuit board according to claim 1, wherein a third dielectric layer intervenes at least a part of a gap between said second dielectric layer and said second conductive-wiring layer.

5. The circuit board according to claim 1, wherein conductor vias that connect together said patterned interconnections in said first conductive-wiring layer and said patterned interconnections in said second conductive-wiring layer have a larger cross-sectional area at a portion in a vicinity of said second conductive-wiring layer than at a portion in a vicinity of said first conductive-wiring layer.

6. The circuit board according to claim 2, wherein said seed layer covers a side surface of said conductor vias that connect together said first conductive-wiring layer and said second conductive-wiring layer, and is formed between said conductor vias and said first conductive-wiring layer.

7. The circuit board according to claim 6, wherein said seed layer is formed between said conductor vias and said second conductive-wiring layer.

8. The circuit board according to claim 6, wherein a resin layer is embedded in a central portion of a surface of said conductor vias near said second conductive-wiring layer.

9. The circuit board according to claim 7, wherein said conductor vias include a conductor post including a uniform-diameter portion, a larger-diameter portion having a lager diameter than said uniform-diameter portion, and a via-plug formed on said conductor post, and said seed layer is formed between said via-plug and said second conductive-wiring layer.

10. The circuit board according to claim 5, wherein said conductor vias has crystal grains larger at a portion near said first conductive-wiring layer than at another portion near said second conductive-wiring layer.

11. The circuit board according to claim 1, wherein a part of said patterned interconnections in said second conductive-wiring layer includes one or a plurality of elements selected from the group consisting of Cu, W, Cr, Pt, Ni, Zn, Fe, Al, C, Mn, Ir, Ti, N and O.

12. The circuit board according to claim 1, wherein a part of said patterned interconnections in said second conductive-wiring layer includes one or a plurality of elements selected from the group consisting of Mg, Mn, Ti, Sr, Ba, Ca, Zn, Al, Ta, Si, Au, Zr, Nb, Hf, Pb, Bi, N and O.

13. The circuit board according to claim 1, wherein a part of said patterned interconnections in said second conductive-wiring layer configures an inductor that has a spiral shape or meander shape.

14. The circuit board according to claim 1, wherein said wiring board embeds therein an intermediate conductive-wiring layer including at least one species of element selected from the group consisting of Fe, Ni, Cr, Co, Cu, Sn, Si and Al.

15. The circuit board according to claim 1, wherein said wiring board embeds therein a plurality of species of dielectric resin layers.

16. The circuit board according to claim 1, wherein at least one of said first and second conductive-wiring layers includes a plurality of said conductor layer, and conductor vias connecting together said first conductive-wiring layer and said second conductive-wiring layer include a conductor via connecting one of said conductor layers and another conductor via connecting another of said conductor layers.

17. The circuit board according to claim 1, wherein said second conductive-wiring layer includes a plurality of said conductor layers, and one of said conductor layers of said second conductive-wiring layer that is connected to said first conductive-wiring layer by a conductor via is farther from said first conductive-wiring layer than said electrode terminals of said functional device.

18. The circuit board according to claim 1, wherein at least one of said first and second conductive-wiring layers includes three conductor layers or more, and one of said conductor layers is connected by a conductor via to another of said conductor layers other than the other of said conductor layers nearest to said one of said conductor layers.

19. The circuit board according to claim 1, wherein said wiring board further embeds an electronic part.

20. The circuit board according to claim 1, wherein said wiring board embeds therein a plurality of said functional devices that are arranged in at least one of a thickness direction and a board-surface direction of said circuit board.

21. The circuit board according to claim 20, wherein adjacent two of said functional devices arranged parallel to said thickness direction of said circuit board are arranged such that said electrode terminals of one of said adjacent two oppose said electrode terminals of the other.

22. The circuit board according to claim 21, wherein a conductive paste or lead-free solder paste including at least one species of element selected from the group consisting of Sn, Ag, Cu, Bi, Zn and Pb connects together said electrode terminals of said one of said adjacent two and said electrode terminals of the other, and connects together two conductor layers connected to said electrode terminals of respective said functional devices.

23. The circuit board according to claim 1, wherein said electrode terminals of said functional device are connected to said conductive-wiring layers by a conductive paste or lead-free solder paste including at least one species of element selected from the group consisting of Sn, Ag, Cu, Bi, Zn and Pb.

24. A stacked circuit board comprising the circuit board according to claim 1 and another circuit board which are stacked one on another in a thickness direction, wherein a conductive paste or lead-free solder paste including at least one species of element selected from the group consisting of Sn, Ag, Cu, Bi, Zn and Pb connects together said wiring layer of said circuit board and a wiring layer of said another circuit board.

25. The circuit board according to claim 1, wherein a solder resist layer having therein an opening on a surface of said second conductive-wiring layer is formed.

26. An electronic equipment comprising the circuit board according to claim 1.

27. A circuit-board manufacturing method comprising: forming at least one first conductive-wiring layer on a supporting substrate; mounting a functional device on said first conductive-wiring layer, covering said functional device by a dielectric resin layer; removing an upper part of said dielectric resin layer so that said surface of said dielectric resin layer is flush with a surface of electrode terminals of said functional device; forming a second conductive-wiring layer that is a conductor wiring layer connected to said electrode terminals, and removing said supporting substrate.

28. The circuit-board manufacturing method according to claim 27, wherein said covering includes further covers a metal layer including at least one species of element selected from the group consisting of Fe, Ni, Cr, Co, Cu, Sn, Si and Al.

29. The circuit-board manufacturing method according to claim 27, further comprising forming a seed layer including at least one species of element selected from the group consisting of Ti, W, Cr, Pt, Au, Cu, Ni, Ag, Sn and Pd, prior to the forming of said conductive-wiring layer, and patterning said seed layer subsequent to the forming of said conductor wiring layer.

30. The circuit-board manufacturing method according to claim 27, further comprising forming a releasing layer on said supporting substrate, prior to the forming of said first conductive-wiring layer.

31. The circuit-board manufacturing method according to claim 27, wherein said supporting substrate includes at least one species of element selected from the group consisting of copper, iron, nickel, chromium, aluminum, titanium, silicon, nitrogen, oxygen and carbon.

32. The circuit-board manufacturing method according to claim 27, wherein the forming of said conductor wiring layer includes consecutively forming first and second conductor layers, and subsequent to the removing of said supporting substrate, removing said first conductor layer to expose said second conductor layer.

33. The circuit-board manufacturing method according to claim 32, further comprising, subsequent to the forming of said first conductor layer, embedding said circuit board in another supporting substrate, and forming another conductive-wiring layer on said another supporting substrate.

34. The circuit-board manufacturing method according to claim 27, further comprising connecting a terminal of an electronic part to said conductor wiring layer by using solder including at least one species of element selected from the group consisting of Sn, Ag, Cu, Bi, Zn and Pb.

35. The circuit-board manufacturing method according to claim 27, further comprising, prior to the removing of said supporting substrate, forming a via-hole to reach said supporting substrate from said conductive-wiring layer, and plating an inside of said via-hole.

36. The circuit-board manufacturing method according to claim 27, further comprising, prior to the forming of said conductor wiring layer, forming a via-hole to reach said supporting substrate from the surface of said dielectric resin layer, and plating an inside of said via-hole.

37. The circuit-board manufacturing method according to claim 36, further comprising filling said plated via-hole with a conductor by using an AD (aerosol deposition) technique.

38. The circuit-board manufacturing method according to claim 27, further comprising, prior to the removing of the upper portion of said dielectric resin layer, forming a via-hole in said dielectric resin layer, forming a seed layer on a bottom portion, a side surface and a top portion of said via-hole and the surface of said dielectric resin layer, forming a conductor via by plating an inside of said via-hole, and grinding said electrode terminals of said functional device and a top surface of said conductor via.

39. The circuit-board manufacturing method according to claim 38, wherein the forming of said conductor via uses an entire-area plating, printing or AD process.

40. The circuit-board manufacturing method according to claim 27, further comprising:
prior to the mounting of said functional device, forming a conductor post on said first conductive-wiring layer; and
subsequent to the covering of said functional device, forming a via-hole in a part of said dielectric resin layer covering said conductor post, and forming a via-plug connecting to said conductor post within said via-hole.

41. A circuit-board manufacturing method comprising of opposing two said circuit boards manufactured by the method according to claim 27 against each other, and connecting together both said circuit boards by using an adhesive layer obtained by embedding conductive paste or solder paste within said via-hole.

42. The circuit-board manufacturing method according to claim 41, wherein at least one of two said functional-device boards is a functional-device board that is prior to removal of said supporting substrate, and the method further comprises removing said supporting substrate from said functional-device board.

43. A circuit-board manufacturing method comprising opposing said circuit board manufactured by the method according to claim 27 against another circuit board, and connecting together both said circuit boards by using an adhesive layer in which a conductive paste or solder paste is embedded within said via-hole.

44. A circuit-board manufacturing method according to claim 41, wherein said conductive paste or lead-free solder paste includes at least one species of element selected from the group consisting of Sn, Ag, Cu, Bi, Zn and Pb.

45. The circuit-board manufacturing method according to claim 27, wherein at least one of said first conductive-wiring layer and said conductor wiring layer is covered by a solder resist layer having therein an opening.
